(19) United States
(12) Patent Application Publication
(10) Pub. No.: US 2024/0274081 A1
(43) Pub. Date: Aug. 15, 2024

(54) DISPLAY DEVICE

(71) Applicant: Samsung Display Co., LTD., Yongin-si (KR)

(72) Inventors: Soo Wan YOON, Yongin-si (KR); Ji Hoon SONG, Yongin-si (KR)

(21) Appl. No.: 18/493,431

(22) Filed: Oct. 24, 2023

(30) Foreign Application Priority Data
Feb. 14, 2023 (KR) 10-2023-0019337

(51) Int. Cl. G09G 3/3233

(52) U.S. Cl. CPC G09G 3/3233; G09G 2330/021

(57) ABSTRACT

A display device includes first and second pixels disposed adjacent to each other. Each of the first and second pixels includes a light-emitting element, a first transistor controlling a driving current flowing in the light-emitting element, a second transistor supplying a data voltage to a first electrode of the first transistor, a third transistor electrically connecting a second electrode of the first transistor and a gate electrode of the first transistor, and a fourth transistor discharging the gate electrode of the first transistor with a first initialization voltage. The first and second pixels share a fourth-first transistor including a first electrode connected to the fourth transistor of the first pixel and the fourth transistor of the second pixel, and a second electrode connected to a first initialization voltage line supplying the first initialization voltage.

This application claims priority to Korean Patent Application No. 10-2023-0019337, filed on Feb. 14, 2023, and all the benefits accruing therefrom under 35 U.S.C. § 119, the content of which in its entirety is herein incorporated by reference.

### BACKGROUND

### 1. Field

The disclosure relates to a display device.

### 2. Description of the Related Art

With an advance of information-oriented society, more and more demands are placed on display devices for displaying images in various ways. The display devices are employed in various electronic devices such as smartphones, digital cameras, laptop computers, navigation devices, and smart televisions. The display device may be a flat panel display device such as a liquid crystal display device, a field emission display device and an organic light-emitting display device. Among the flat panel display devices, in the light-emitting display device, since each of pixels of a display panel includes a light-emitting element capable of emitting light by itself, an image may be displayed without a backlight unit providing light to the display panel.

### SUMMARY

Features of the disclosure provide a display device capable of improving leakage current characteristics and preventing line defects or line shorts in pixel circuits.

However, features of the disclosure are not restricted to the one set forth herein. The above and other features of the disclosure will become more apparent to one of ordinary skill in the art to which the disclosure pertains by referencing the detailed description of the disclosure given below.

In an embodiment of the disclosure, a display device includes first and second pixels disposed adjacent to each other. Each of the first and second pixels includes a light-emitting element, a first transistor controlling a driving current flowing in the light-emitting element, a second transistor supplying a data voltage to a first electrode of the first transistor, a third transistor electrically connecting a second electrode of the first transistor and a gate electrode of the first transistor, and a fourth transistor discharging the gate electrode of the first transistor with a first initialization voltage. The first and second pixels share a fourth-first transistor including a first electrode connected to the fourth transistor of the first pixel and the fourth transistor of the second pixel, and a second electrode connected to a first initialization voltage line supplying the first initialization voltage.

In an embodiment, the first transistor and the second transistor may include silicon-based semiconductor area. The third transistor, the fourth transistor, and the fourth-first transistor may include an oxide-based semiconductor area.

In an embodiment, the second transistor may receive a first gate signal of a first voltage level during a first period to be turned on. The third transistor may receive a second gate signal of a second voltage level higher than the first voltage level during a second period different from the first period to be turned on. The fourth transistor and the fourth-first transistor may receive a third gate signal of the second voltage level during a third period different from the first and second periods to be turned on.

In an embodiment, each of the first and second pixels may further include a fifth transistor electrically connecting a driving voltage line supplying a driving voltage and the first electrode, a sixth transistor electrically connecting the second electrode of the first transistor and a first electrode of the light-emitting element, and a seventh transistor electrically connecting the first electrode of the light-emitting element and a second initialization voltage line supplying a second initialization voltage different from the first initialization voltage.

In an embodiment, the fifth transistor, the sixth transistor, and the seventh transistor may include a silicon-based semiconductor area.

In an embodiment, the third transistor includes a semiconductor area, a gate electrode disposed on the semiconductor area to overlap the semiconductor area, and a bias electrode disposed below the semiconductor area to overlap the semiconductor area. The bias electrode of the third transistor may be electrically connected to the gate electrode of the third transistor.

In an embodiment, the display device may further include a substrate, a first active layer disposed on the substrate and including a first material, a first gate layer disposed on the first active layer, a second gate layer disposed on the first gate layer, a second active layer disposed on the second gate layer and including a second material different from the first material, and a third gate layer disposed on the second active layer.

In an embodiment, semiconductor areas of the first transistor and the second transistor may be disposed in the first active layer. Semiconductor areas of the third transistor, the fourth transistor, and the fourth-first transistor may be disposed in the second active layer.

In an embodiment, the display device may further include a first gate line disposed in the first gate layer to supply a first gate signal to a gate electrode of the second transistor, a second gate line disposed in the third gate layer to supply a second gate signal different from the first gate signal to a gate electrode of the third transistor, and a third gate line disposed in the third gate layer to supply a third gate signal different from the first and second gate signals to each gate electrode of the fourth transistor and the fourth-first transistor.

In an embodiment, the first initialization voltage line may be disposed on the third gate layer to extend in a first direction. The first initialization voltage line may include a first extension portion extending in a second direction crossing the first direction, and a second extension portion extending in a third direction crossing the second direction and connected to the fourth-first transistor.

In an embodiment, the first extension portion may cross the third gate line and may do not overlap the semiconductor area of the fourth-first transistor.

In an embodiment, the first initialization voltage line may be disposed on the third gate layer to extend in a first direction. The first initialization voltage line may include an extension portion extending in a second direction crossing the first direction to be connected to the fourth-first transistor.

In an embodiment, the extension portion may cross the third gate line and may overlap the semiconductor area of the fourth-first transistor.

In an embodiment of the disclosure, a display device includes a display panel including a display area including a plurality of pixels and a non-display area surrounding the display area. Each of the plurality of pixels includes a light-emitting element, a first transistor controlling a driving current flowing in the light-emitting element, a second transistor supplying a data voltage to a first electrode of the first transistor, a third transistor electrically connecting a second electrode of the first transistor and a gate electrode of the first transistor, and a fourth transistor discharging the gate electrode of the first transistor with a first initialization voltage. The display area includes a first bias voltage line supplying a first bias voltage to a bias electrode of the third transistor, and a second bias voltage line supplying a second bias voltage to a bias electrode of the fourth transistor.

In an embodiment, the display device may further include a circuit board supplying voltages and signals to the display panel. The display panel may further include a display pad unit connected to the circuit board. The non-display area may include a bias lead line electrically connecting the first bias voltage line or the second bias voltage line to the display pad unit.

In an embodiment, the first bias voltage line may be electrically insulated from a gate electrode of the third transistor, and the second bias voltage line may be electrically insulated from a gate electrode of the fourth transistor.

In an embodiment of the disclosure, a display device includes a plurality of pixels arranged along a plurality of rows and a plurality of columns, a first initialization voltage line supplying a first initialization voltage to the plurality of pixels, a second initialization voltage line supplying a second initialization voltage different from the first initialization voltage to the plurality of pixels, and a driving voltage line supplying a driving voltage to the plurality of pixels. Each of the plurality of pixels includes a light-emitting element, a first transistor controlling a driving current flowing in the light-emitting element, a second transistor supplying a data voltage to a first electrode of the first transistor, a third transistor electrically connecting a second electrode of the first transistor and a gate electrode of the first transistor, a fourth transistor discharging the gate electrode of the first transistor with the first initialization voltage, a fifth transistor electrically connecting the driving voltage line and the first electrode of the first transistor, a sixth transistor electrically connecting the second electrode of the first transistor and a first electrode of the light-emitting element, and a seventh transistor electrically connecting the first electrode of the light-emitting element and the second initialization voltage line. The first and second initialization voltage lines are disposed between adjacent rows of some of the plurality of rows and are not disposed between the adjacent rows of some others of the plurality of rows.

In an embodiment, the first initialization voltage line may include a horizontal portion extending in a first direction and a vertical portion connected to the horizontal portion and extending in a second direction crossing the first direction. The second initialization voltage line may include a horizontal portion extending in the first direction and a vertical portion connected to the horizontal portion and extending in the second direction.

In an embodiment, the horizontal portion of the second initialization voltage line may be provided in plural, and the horizontal portion of the first initialization voltage line may be disposed between the horizontal portions of the second initialization voltage line and may cross the vertical portion of the second initialization voltage line.

In an embodiment, the vertical portion of the first initialization voltage line may be provided in plural, the vertical portions of the first initialization voltage line adjacent in the second direction may be spaced apart from each other with the horizontal portion of the second initialization voltage line interposed therebetween. The vertical portions of the second initialization voltage line adjacent in the second direction may be spaced apart from each other with the horizontal portion of the first initialization voltage line interposed therebetween.

In accordance with the display device in embodiments, by sharing a transistor supplying an initialization voltage between adjacent pixels, leakage current characteristics may be improved, and line defects or line shorts of the pixel circuit may be prevented by optimizing the design of the pixel circuit.

In accordance with the display device in embodiments, by supplying a bias voltage different from a gate signal to a bias electrode of a transistor in which leakage current may occur, output characteristics may be improved by improving leakage current characteristics and stabilizing an electric field.

In accordance with the display device in embodiments, since the initialization voltage line is disposed between adjacent rows of some of the plurality of rows and not disposed between adjacent rows of other portions of the plurality of rows, it is possible to design a high-resolution design and reduce the line defect rate.

The effects of the disclosure are not limited to the aforementioned effects, and various other effects are included in the specification.

### BRIEF DESCRIPTION OF THE DRAWINGS

The above and other embodiments, advantages and features of the disclosure will become more apparent by describing in detail embodiments thereof with reference to the attached drawings, in which:

FIG. 1 is a perspective view showing an embodiment of a display device;

FIG. 2 is a cross-sectional view illustrating an embodiment of a display device:

FIG. 3 is a plan view illustrating an embodiment of a display unit of a display device:

FIG. 4 is a block diagram illustrating an embodiment of a display panel and a display driver:

FIG. 5 is a circuit diagram illustrating an embodiment of a pixel of a display device:

FIG. 6 is a waveform diagram of signals supplied to the pixel shown in FIG. 5;

FIG. 7 is a layout diagram illustrating a first and second pixels of FIG. 5:

FIG. 8 is a layout diagram illustrating a first pixel of FIG. 7:

FIG. 9 is a cross-sectional view taken along line I-I′ of FIG. 8;

FIG. 10 is a plan view illustrating an embodiment of a first initialization voltage line in a display device:

FIG. 11 is a plan view of another embodiment of a first initialization voltage line in a display device:

FIG. 12 is a circuit diagram illustrating another embodiment of a pixel of a display device:

FIG. 13 is a plan view illustrating another embodiment of a bias voltage line of a display device:

FIG. 14 is a plan view illustrating another embodiment of first and second initialization voltage lines of a display device:

FIG. 15 is a diagram illustrating a connection relationship between a pixel and first and second initialization voltage lines in a display device of FIG. 14;

FIG. 16 is a plan view illustrating another embodiment of first and second initialization voltage lines of a display device; and

FIG. 17 is a diagram illustrating a connection relationship between a pixel and first and second initialization voltage lines in a display device of FIG. 16.

### DETAILED DESCRIPTION

In the following description, for the purposes of explanation, numerous specific details are set forth in order to provide a thorough understanding of various embodiments or implementations of the disclosure. As used herein “embodiments” and “implementations” are interchangeable words that are non-limiting examples of devices or methods employing one or more of the disclosure disclosed herein. It is apparent, however, that various embodiments may be practiced without these specific details or with one or more equivalent arrangements. In other instances, structures and devices are shown in block diagram form in order to avoid unnecessarily obscuring various embodiments. Further, various embodiments may be different, but do not have to be exclusive nor limit the disclosure. For example, specific shapes, configurations, and characteristics of an embodiment may be used or implemented in other embodiments without departing from the disclosure.

Unless otherwise specified, the illustrated embodiments are to be understood as providing features of varying detail of some ways in which the disclosure may be implemented in practice. Therefore, unless otherwise specified, the features, components, modules, layers, films, panels, regions, and/or features, etc. (hereinafter individually or collectively referred to as “elements”), of the various embodiments may be otherwise combined, separated, interchanged, and/or rearranged without departing from the disclosure.

The use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Further, in the accompanying drawings, the size and relative sizes of elements may be exaggerated for clarity and/or descriptive purposes. When an embodiment may be implemented differently, a specific process order may be performed differently from the described order. For example, two consecutively described processes may be performed substantially at the same time or performed in an order opposite to the described order. Also, like reference numerals denote like elements.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements.

Further, the X-axis, the Y-axis, and the Z-axis are not limited to three axes of a rectangular coordinate system, and thus the X-, Y-, and Z-axes, and may be interpreted in a broader sense. For example, the X-axis, the Y-axis, and the Z-axis may be perpendicular to one another, or may represent different directions that are not perpendicular to one another.

For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, ZZ, or the like. As used herein, the term “and/or” includes any and all combinations of one or more of the associated listed items.

Although the terms “first,” “second,” and the like may be used herein to describe various types of elements, these elements should not be limited by these terms. These terms are used to distinguish one element from another element. Thus, a first element discussed below could be termed a second element without departing from the teachings of the disclosure.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the term “below” can encompass both an orientation of above and below. Furthermore, the apparatus may be otherwise oriented (e.g., rotated 90 degrees or at other orientations), and, as such, the spatially relative descriptors used herein should be interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

Various embodiments are described herein with reference to cross-sectional and/or exploded illustrations that are schematic illustrations of embodiments and/or intermediate structures. As such, variations from the shapes of the illustrations as a result, for example, of manufacturing techniques and/or tolerances, are to be expected. Thus, embodiments disclosed herein should not necessarily be construed as limited to the particular illustrated shapes of regions, but are to include deviations in shapes that result from, for instance, manufacturing. In this manner, regions illustrated in the drawings may be schematic in nature, and the shapes of these regions may not reflect actual shapes of regions of a device and, as such, are not necessarily intended to be limiting.

As customary in the field, some embodiments are described and illustrated in the accompanying drawings in terms of functional blocks, units, parts, and/or modules. Those skilled in the art will appreciate that these blocks, units, parts, and/or modules are physically implemented by electronic (or optical) circuits, such as logic circuits, discrete components, microprocessors, hard-wired circuits, memory elements, wiring connections, and the like, which may be formed using semiconductor-based fabrication techniques or other manufacturing technologies. In the case of the blocks, units, parts, and/or modules being implemented by microprocessors or other similar hardware, they may be programmed and controlled using software (e.g., microcode) to perform various functions discussed herein and may optionally be driven by firmware and/or software. It is also contemplated that each block, unit, part, and/or module may be implemented by dedicated hardware, or as a combination of dedicated hardware to perform some functions and a processor (e.g., one or more programmed microprocessors and associated circuitry) to perform other functions. Also, each block, unit, part, and/or module of some embodiments may be physically separated into two or more interacting and discrete blocks, units, parts, and/or modules without departing from the scope of the disclosure. Further, the blocks, units, parts, and/or modules of some embodiments may be physically combined into more complex blocks, units, parts, and/or modules without departing from the scope of the disclosure.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

Hereinafter, detailed embodiments of the disclosure is described with reference to the accompanying drawings.

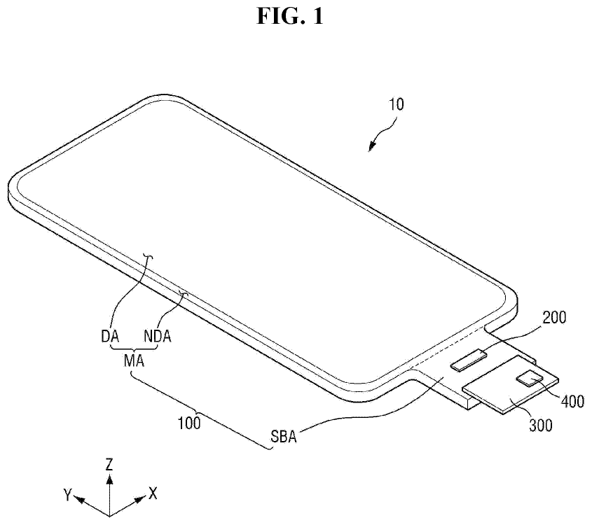

FIG. 1 is a perspective view showing an embodiment of a display device.

Referring to FIG. 1, a display device 10 may be applied to portable electronic devices such as a mobile phone, a smartphone, a tablet personal computer, a mobile communication terminal, an electronic organizer, an electronic book, a portable multimedia player (“PMP”), a navigation system, an ultra mobile PC (“UMPC”) or the like. In an embodiment, the display device 10 may be applied as a display unit of a television, a laptop, a monitor, a billboard, or an Internet-of-Things (“IoT”) device, for example. In another embodiment, the display device 10 may be applied to wearable devices such as a smart watch, a watch phone, a glasses type display, or a head disposed (e.g., mounted) display (“HMD”).

The display device 10 may have a planar shape similar to a quadrilateral shape. In an embodiment, the display device 10 may have a shape similar to a quadrilateral shape, in a plan view, having short sides in an X-axis direction and long sides in a Y-axis direction, for example. The corner where the short side in the X-axis direction and the long side in the Y-axis direction meet may be rounded to have a predetermined curvature or may be right-angled. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, and a touch driver 400.

The display panel 100 may include a main region MA and a sub-region SBA.

The main region MA may include a display area DA including pixels displaying an image and a non-display area NDA disposed around the display area DA. The display area DA may emit light from a plurality of emission areas or a plurality of opening areas. In an embodiment, the display panel 100 may include a pixel circuit including switching elements, a pixel defining layer defining an emission area or an opening area, and a self-light-emitting element, for example.

In an embodiment, the self-light-emitting element may include at least one of an organic light-emitting diode (“LED”) including an organic light-emitting layer, a quantum dot LED including a quantum dot light-emitting layer, an inorganic LED including an inorganic semiconductor, or a micro LED, for example, but is not limited thereto.

The non-display area NDA may be an area outside the display area DA. The non-display area NDA may be defined as an edge area of the main region MA of the display panel 100. The non-display area NDA may include a scan driver (not illustrated) that supplies scan signals to the scan lines, and fan-out lines (not illustrated) that connect the display driver 200 to the display area DA.

The sub-region SBA may extend from one side of the main region MA. The sub-region SBA may include a flexible material which may be bent, folded or rolled. In an embodiment, when the sub-region SBA is bent, the sub-region SBA may overlap the main region MA in a thickness direction (Z-axis direction), for example. The sub-region SBA may include the display driver 200 and a pad unit connected to the circuit board 300. Optionally, the sub-region SBA may be omitted, and the display driver 200 and the pad unit may be arranged in the non-display area NDA.

The display driver 200 may output signals and voltages for driving the display panel 100. The display driver 200 may supply data voltages to data lines. The display driver 200 may supply a power voltage to the power line and may supply a scan control signal to the scan driver. The display driver 200 may be formed as an integrated circuit (“IC”) and disposed (e.g., mounted) on the display panel 100 by a chip on glass (“COG”) method, a chip on plastic (“COP”) method, or an ultrasonic bonding method. In an embodiment, the display driver 200 may be disposed in the sub-region SBA, and may overlap the main region MA in the thickness direction (Z-axis direction) by bending of the sub-region SBA, for example. In another embodiment, the display driver 200 may be disposed (e.g., mounted) on the circuit board 300.

The circuit board 300 may be attached to the pad unit of the display panel 100 by an anisotropic conductive film (“ACF”). Lead lines of the circuit board 300 may be electrically connected to a pad unit of the display panel 100. The circuit board 300 may be a flexible printed circuit board, a printed circuit board, or a flexible film such as a chip on film.

The touch driver 400 may be disposed (e.g., mounted) on the circuit board 300. The touch driver 400 may be electrically connected to a touch sensing unit of the display panel 100. The touch driver 400 may supply a touch driving signal to a plurality of touch electrodes of the touch sensing unit and may sense an amount of change in capacitance between the plurality of touch electrodes. In an embodiment, the touch driving signal may be a pulse signal having a predetermined frequency, for example. The touch driver 400 may calculate whether an input is made and input coordinates based on an amount of change in capacitance between the plurality of touch electrodes. The touch driver 400 may include or consist of an IC.

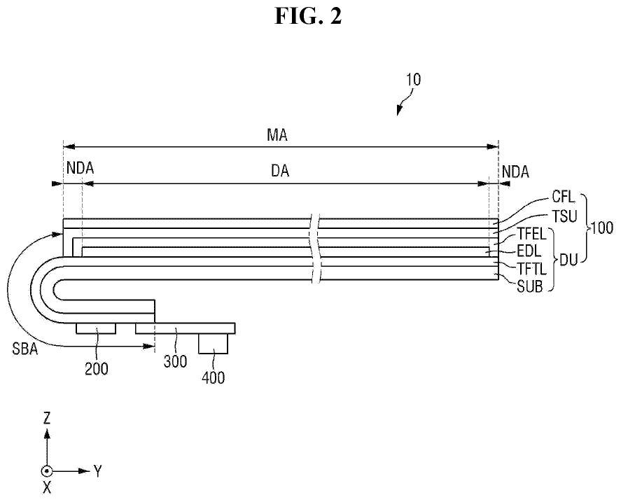

FIG. 2 is a cross-sectional view illustrating an embodiment of a display device.

Referring to FIG. 2, the display panel 100 may include a display unit DU, a touch sensing unit TSU, and a color filter layer CFL. The display unit DU may include a substrate SUB, a thin film transistor layer TFTL, a light-emitting element layer EDL, and an encapsulation layer TFEL.

The substrate SUB may be a base substrate or a base member. The substrate SUB may be a flexible substrate which may be bent, folded or rolled. In an embodiment, the substrate SUB may include a polymer resin such as polyimide (“PI”), for example, but is not limited thereto. In another embodiment, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include scan lines, data lines, power lines, scan control lines, fan-out lines that connect the display driver 200 to the data lines, and lead lines that connect the display driver 200 to the pad unit. Each of the thin film transistors may include a semiconductor area, a source electrode, a drain electrode, and a gate electrode. In an embodiment, when the scan driver is formed in the non-display area NDA of the display panel 100, the scan driver may include thin film transistors, for example.

The thin film transistor layer TFTL may be disposed in the display area DA, the non-display area NDA, and the sub-region SBA. Thin film transistors, scan lines, data lines, and power lines of each of the pixels of the thin film transistor layer TFTL may be disposed in the display area DA. Scan control lines and fan-out lines of the thin film transistor layer TFTL may be disposed in the non-display area NDA. The lead lines of the thin film transistor layer TFTL may be disposed in the sub-region SBA.

The light-emitting element layer EDL may be disposed on the thin film transistor layer TFTL. The light-emitting element layer EDL may include a plurality of light-emitting elements in which a first electrode, a light-emitting layer, and a second electrode are sequentially stacked to emit light, and a pixel defining layer defining pixels. A plurality of light-emitting elements of the light-emitting element layer EDL may be disposed in the display area DA.

In an embodiment, the light-emitting layer may be an organic light-emitting layer including an organic material, for example. The light-emitting layer may include a hole transporting layer, an organic light-emitting layer, and an electron transporting layer. When the first electrode receives a predetermined voltage through the thin film transistor of the thin film transistor layer TFTL and the second electrode receives a cathode voltage, holes and electrons may be transferred to the organic light-emitting layer through the hole transporting layer and the electron transporting layer, respectively and may be combined with each other to emit light in the organic light-emitting layer. In an embodiment, the first electrode may be an anode electrode or a pixel electrode, and the second electrode may be a cathode electrode or a common electrode, for example, but the disclosure is not limited thereto.

In another embodiment, the plurality of light-emitting elements may include a quantum dot light-emitting diode including a quantum dot light-emitting layer, an inorganic light-emitting diode including an inorganic semiconductor, or a micro light-emitting diode.

The encapsulation layer TFEL may cover the top surface and the side surface of the light-emitting element layer EDL, and may protect the light-emitting element layer EDL. The encapsulation layer TFEL may include at least one inorganic layer and at least one organic layer for encapsulating the light-emitting element layer EDL.

The touch sensing unit TSU may be disposed on the encapsulation layer TFEL. The touch sensing unit TSU may include a plurality of touch electrodes for sensing a user's touch in a capacitive manner, and touch lines connecting the plurality of touch electrodes to the touch driver 400. In an embodiment, the touch sensing unit TSU may sense the user's touch by a mutual capacitance method or a self-capacitance method, for example.

In another embodiment, the touch sensing unit TSU may be disposed on a separate substrate disposed on the display unit DU. In this case, the substrate SUB supporting the touch sensing unit TSU may be a base member that encapsulates the display unit DU.

The plurality of touch electrodes of the touch sensing unit TSU may be disposed in a touch sensor area overlapping the display area DA. The touch lines of the touch sensing unit TSU may be disposed in a touch peripheral area that overlaps the non-display area NDA.

The color filter layer CFL may be disposed on the touch sensing unit TSU. The color filter layer CFL may include a plurality of color filters respectively corresponding to the plurality of emission areas. Each of the color filters may selectively transmit light of a predetermined wavelength and may block or absorb light of a different wavelength. The color filter layer CFL may absorb a part of light coming from the outside of the display device 10 to reduce reflected light due to external light. Accordingly, the color filter layer CFL may prevent color distortion caused by reflection of the external light.

Since the color filter layer CFL is directly disposed on the touch sensing unit TSU, a separate substrate for the color filter layer CFL may not be desired in the display device 10. Therefore, the thickness of the display device 10 may be relatively reduced.

The sub-region SBA of the display panel 100 may extend from one side of the main region MA. The sub-region SBA may include a flexible material which may be bent, folded or rolled. In an embodiment, when the sub-region SBA is bent, the sub-region SBA may overlap the main region MA in a thickness direction (Z-axis direction), for example. The sub-region SBA may include the display driver 200 and the pad unit electrically connected to the circuit board 300.

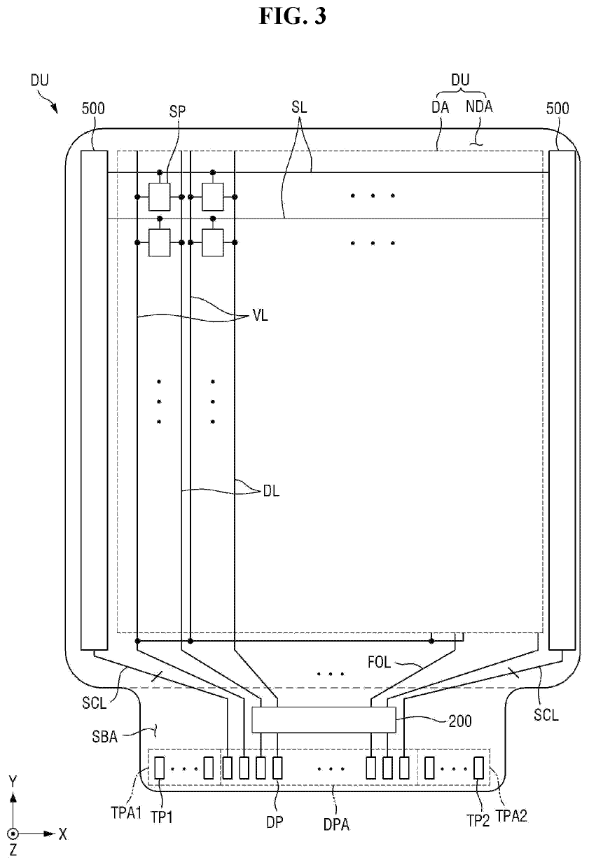

FIG. 3 is a plan view illustrating an embodiment of a display unit of a display device.

Referring to FIG. 3, the display unit DU may include the display area DA and the non-display area NDA.

The display area DA, which is an area for displaying an image, may be defined as the central area of the display panel 100. The display area DA may include a plurality of pixels SP, a plurality of scan lines SL, a plurality of data lines DL, and a plurality of power lines VL. Each of the plurality of pixels SP may be defined as the smallest unit that outputs light.

The plurality of scan lines SL may supply the scan signals received from a scan driver 500 to the plurality of pixels SP. The plurality of scan lines SL may extend in an X-axis direction and may be spaced apart from each other in a Y-axis direction that crosses the X-axis direction.

The plurality of data lines DL may supply the data voltages received from the display driver 200 to the plurality of pixels SP. The plurality of data lines DL may extend in the Y-axis direction and may be spaced apart from each other in the X-axis direction.

The plurality of power lines VL may supply the power voltage received from a display pad unit DP to the plurality of pixels SP. Here, the power voltage may be at least one of a driving voltage, a relatively high potential voltage, an initialization voltage, a reference voltage, a bias voltage, or a relatively low potential voltage. The plurality of power lines VL may extend in the Y-axis direction and may be spaced apart from each other in the X-axis direction.

The non-display area NDA may surround the display area DA. The non-display area NDA may include a scan driver 500, fan-out lines FOL, and scan control lines SCL. The scan driver 500 may generate a plurality of scan signals based on the scan control signal, and may sequentially supply the plurality of scan signals to the plurality of scan lines SL according to a set order.

The fan-out lines FOL may extend from the display driver 200 to the display area DA. The fan-out lines FOL may supply the data voltage received from the display driver 200 to the plurality of data lines DL.

The scan control line SCL may extend from the display pad unit DP to the scan driver 500. The scan control line SCL may supply the scan control signal received from the display pad unit DP to the scan driver 500.

The sub-region SBA may include the display driver 200, a display pad area DPA, and first and second touch pad areas TPA1 and TPA2.

The display driver 200 may output signals and voltages for driving the display panel 100 to the fan-out lines FOL. The display driver 200 may supply a data voltage to the data line DL through the fan-out lines FOL. The data voltage may be supplied to the plurality of pixels SP to determine the luminance of the plurality of pixels SP.

The display pad area DPA, the first touch pad area TPA1, and the second touch pad area TPA2 may be disposed at the edge of the sub-region SBA. The display pad area DPA, the first touch pad area TPA1, and the second touch pad area TPA2 may be electrically connected to the circuit board 300 by a low-resistance and high-reliability material such as an anisotropic conductive film or a self assembly anisotropic conductive paste (“SAP”).

The display pad area DPA may include a plurality of display pad units DP. The plurality of display pad units DP may be electrically connected to a graphic system through the circuit board 300. The plurality of display pad units DP may be connected to the circuit board 300 to receive digital video data, and may supply the digital video data to the display driver 200. The plurality of display pad units DP may supply scan control signals to the scan driver 500 through the scan control line SCL.

The first touch pad area TPA1 may be disposed on one side of the display pad area DPA, and may include a plurality of first touch pad units TP1. The plurality of first touch pad units TP1 may be electrically connected to the touch driver 400 disposed on the circuit board 300. The plurality of first touch pad units TP1 may supply a touch driving signal to the plurality of driving electrodes through a plurality of driving lines.

The second touch pad area TPA2 may be disposed on the other side of the display pad area DPA, and may include a plurality of second touch pad units TP2. The plurality of second touch pad units TP2 may be electrically connected to the touch driver 400 disposed on the circuit board 300. The touch driver 400 may receive a touch sensing signal through a plurality of sensing lines connected to the plurality of second touch pad units TP2, and may sense a change in mutual capacitance between the driving electrode and a sensing electrode.

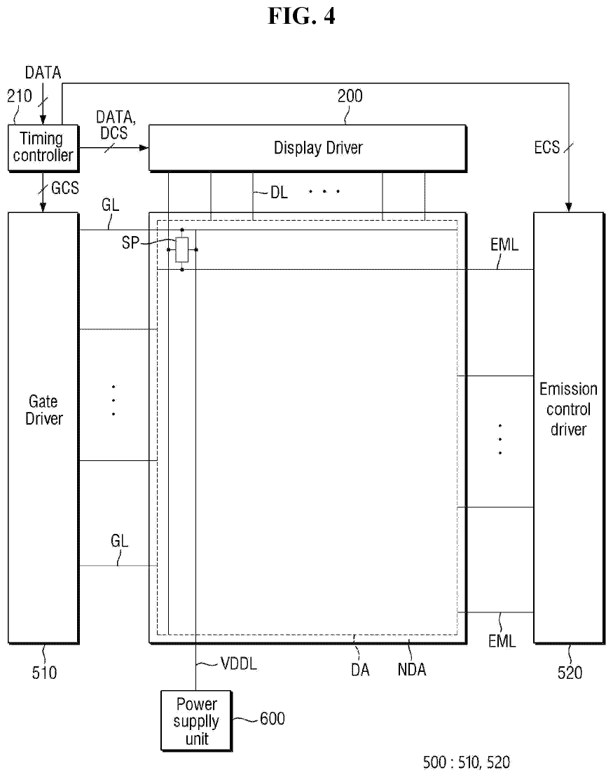

FIG. 4 is a block diagram illustrating an embodiment of a display panel and a display driver.

Referring to FIG. 4, the display panel 100 may include the display area DA and the non-display area NDA.

The display area DA may include a plurality of pixels SP, a plurality of driving voltage lines VDDL, a plurality of gate lines GL, a plurality of emission control lines EML, and a plurality of data lines DL connected to the plurality of pixels SP.

Each of the pixels SP may be connected to the gate line GL, the data line DL, the emission control line EML, and the driving voltage line VDDL. Each of the pixels SP may include at least one transistor, a light-emitting element and a capacitor.

The gate lines GL may extend in the X-axis direction and may be spaced apart from each other in the Y-axis direction that crosses the X-axis direction. The gate lines GL may sequentially supply gate signals to the plurality of pixels SP.

The emission control lines EML may extend in the X-axis direction and may be spaced apart from each other in the Y-axis direction. The emission control lines EML may sequentially supply emission signals to the plurality of pixels SP.

The data lines DL may extend in the Y-axis direction and may be spaced apart from each other in the X-axis direction. The data lines DL may supply the data voltage to the plurality of pixels SP. The data voltage may determine the luminance of each of the plurality of pixels SP.

The driving voltage lines VDDL may extend in the Y-axis direction and may be spaced apart from each other in the X-axis direction. The driving voltage lines VDDL may supply a driving voltage to the plurality of pixels SP. The driving voltage may be a relatively high potential voltage for driving the light-emitting elements of the pixels SP.

A timing controller 210 may receive digital video data DATA and timing signals from the circuit board 300. The timing controller 210 may generate a data control signal DCS based on the timing signals. The timing controller 210 may control the operation timing of the display driver 200 by supplying the digital video data DATA and the data control signal DCS to the display driver 200. The display driver 200 may convert the digital video data DATA into analog data voltages and output them to the data lines DL. The timing controller 210 may generate a gate control signal GCS based on the timing signals. The timing controller 210 may supply the gate control signal GCS to a gate driver 510 to control the operation timing of the gate driver 510. The timing controller 210 may generate an emission control signal ECS based on the timing signals. The timing controller 210 may supply the emission control signal ECS to an emission control driver 520 to control the operation timing of the emission control driver 520.

The gate driver 510 and the emission control driver 520 may be disposed on the left or right side of the non-display area NDA. In an embodiment, the gate driver 510 and the emission control driver 520 may be disposed on the left and right sides of the non-display area NDA, for example, but are not limited thereto. In another embodiment, the gate driver 510 may be disposed on the left side of the non-display area NDA, and the emission control driver 520 may be disposed on the right side of the non-display area NDA.

The gate driver 510 may include a plurality of transistors and generate gate signals based on the gate control signal GCS. Gate signals of the gate driver 510 may select pixels SP to which the data voltage is supplied, and the selected pixels SP may receive the data voltage through the data lines DL. The emission control driver 520 may include a plurality of transistors and generate emission signals based on the emission control signal ECS. In an embodiment, the transistors of the gate driver 510 and the transistors of the emission control driver 520 may be formed in the same layer as the transistors of each pixel SP, for example. The gate driver 510 may supply gate signals to the gate lines GL, and the emission control driver 520 may supply emission signals to the emission control lines EML.

A power supply unit 600 may supply a power voltage to the display driver 200 and the display panel 100. The power supply unit 600 may generate a driving voltage and supply it to the driving voltage line VDDL, generate an initialization voltage and supply it to the initialization voltage line, generate a bias voltage and supply it to a bias voltage line, and generate a relatively low potential voltage and supply it to a common electrode common to the light-emitting elements of the plurality of pixels.

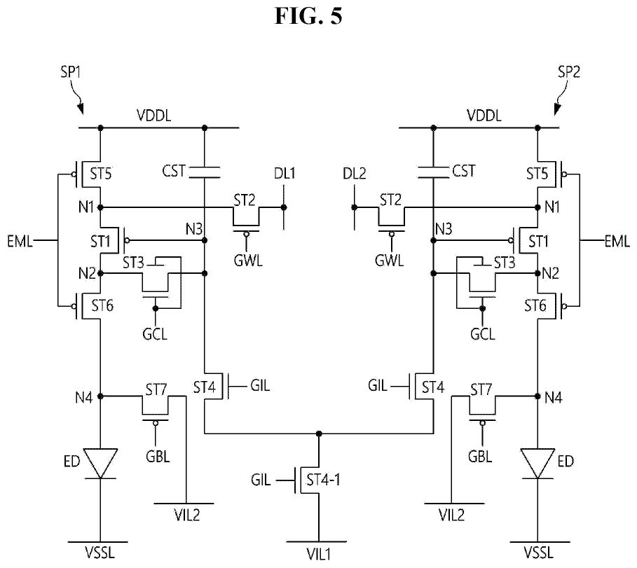

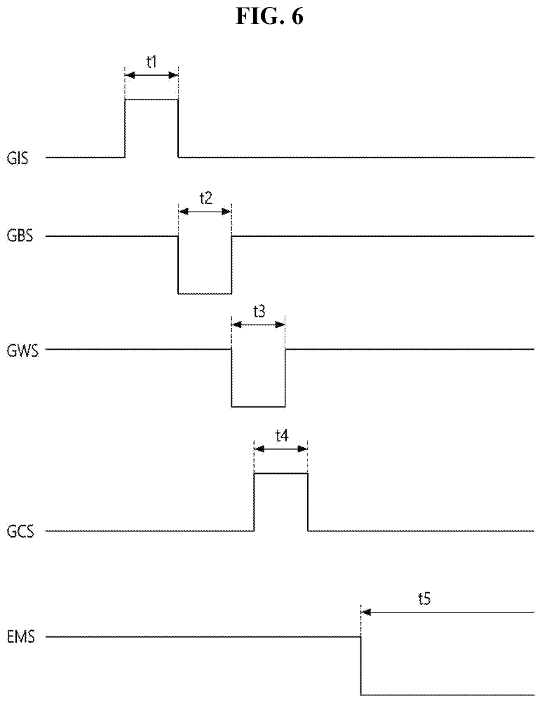

FIG. 5 is a circuit diagram illustrating an embodiment of a pixel of a display device, and FIG. 6 is a waveform diagram of signals supplied to the pixel shown in FIG. 5.

Referring to FIGS. 5 and 6, the pixel SP may include a first pixel SP1 and a second pixel SP2.

The first pixel SP1 may be connected to a first gate line GWL, a second gate line GCL, a third gate line GIL, a fourth gate line GBL, an emission control line EML, a first data line DL1, a driving voltage line VDDL, a first initialization voltage line VIL1, a second initialization voltage line VIL2, and a low potential line VSSL.

The second pixel SP2 may be connected to the first gate line GWL, the second gate line GCL, the third gate line GIL, the fourth gate line GBL, the emission control line EML, a second data line DL2, the driving voltage line VDDL, the first initialization voltage line VIL1, the second initialization voltage line VIL2, and the low potential line VSSL.

Each of the first and second pixels SP1 and SP2 may include a light-emitting element ED and a pixel circuit driving the light-emitting element ED. The pixel circuit may include a plurality of switching elements and a capacitor CST. The plurality of switching elements may include first to seventh transistors ST1, ST2, ST3, ST4, ST5, ST6, and ST7. The first and second pixels SP1 and SP2 may share a fourth-first transistor ST4-1.

The first transistor ST1 may control a driving current supplied to the light-emitting element ED. The first transistor ST1 may include a gate electrode, a first electrode, and a second electrode. The gate electrode of the first transistor ST1 may be connected to a third node N3, the first electrode thereof may be connected to a first node N1, and the second electrode thereof may be connected to a second node N2. In an embodiment, the first electrode of the first transistor ST1 may be a source electrode and the second electrode thereof may be a drain electrode, for example, but the disclosure is not limited thereto.

The first transistor ST1 may control a source-drain current Isd (hereinafter, also referred to as “driving current”) according to the data voltage applied to the gate electrode. The driving current Isd flowing through the channel of the first transistor ST1 may be proportional to the square of a difference between a threshold voltage Vth and a voltage Vsg between the source electrode and the gate electrode of the first transistor ST1 (Isd=k×(Vsg−Vth)²). Here, k denotes a proportional coefficient determined by the structure and physical characteristics of the first transistor ST1, Vsg denotes a source-gate voltage of the first transistor ST1, and Vth denotes a threshold voltage of the first transistor ST1.

The light-emitting element ED may emit light by receiving the driving current Isd. The emission amount or the luminance of the light-emitting element ED may be proportional to the magnitude of the driving current Isd. The light-emitting element ED may include a first electrode, a second electrode, and a light-emitting layer disposed between the first electrode and the second electrode. The first electrode of the light-emitting element ED may be connected to a fourth node N4. The first electrode of the light-emitting element ED may be connected to the second electrode of the sixth transistor ST6 and the second electrode of the seventh transistor ST7 through the fourth node N4. In an embodiment, the first electrode of the light-emitting element ED may be an anode electrode or a pixel electrode, and the second electrode thereof may be a cathode electrode or a common electrode, for example, but the disclosure is not limited thereto.

The second transistor ST2 may be turned on by a first gate signal GWS of the first gate line GWL to electrically connect the data line DL to the first node N1 which is the first electrode of the first transistor ST1. The second transistor ST2 may be turned on based on the first gate signal GWS to supply the data voltage to the first node N1. The gate electrode of the second transistor ST2 may be connected to the first gate line GWL, the first electrode thereof may be connected to the data line DL, and the second electrode thereof may be connected to the first node N1. The second electrode of the second transistor ST2 may be connected to the first electrode of the first transistor ST1 and the second electrode of the fifth transistor ST5 through the first node N1. In an embodiment, the first electrode of the second transistor ST2 may be a source electrode and the second electrode thereof may be a drain electrode, for example, but the disclosure is not limited thereto.

The third transistor ST3 may be turned on by a second gate signal GCS of the second gate line GCL to electrically connect the second node N2, which is the second electrode of the first transistor ST1, to the third node N3, which is the gate electrode of the first transistor ST1. The gate electrode of the third transistor ST3 may be connected to the second gate line GCL, the first electrode thereof may be connected to the second node N2, and the second electrode thereof may be connected to the third node N3. The first electrode of the third transistor ST3 may be connected to the second electrode of the first transistor ST1 and the first electrode of the sixth transistor ST6 through the second node N2. The second electrode of the third transistor ST3 may be connected to the gate electrode of the first transistor ST1, the first electrode of the fourth transistor ST4, and a first capacitor electrode of a capacitor CST through the third node N3. In an embodiment, the first electrode of the third transistor ST3 may be a drain electrode and the second electrode thereof may be a source electrode, for example, but is not limited thereto.

The third transistor ST3 may include a bias electrode. The bias electrode of the third transistor ST3 may overlap the semiconductor area of the third transistor ST3. The bias electrode of the third transistor ST3 may be electrically connected to a gate electrode of the third transistor ST3. The bias electrode of the third transistor ST3 may improve leakage current characteristics, thereby stabilizing the electric field of the third transistor ST3 and improving output characteristics.

The fourth transistor ST4 and a fourth-first transistor ST4-1 may be turned on by a third gate signal GIS of the third gate line GIL to electrically connect the first initialization voltage line VIL1 to the third node N3, which is the gate electrode of the first transistor ST1. The fourth transistor ST4 and the fourth-first transistor ST4-1 may be turned on based on the third gate signal GIS, thereby discharging the gate electrode of the first transistor ST1 with a first initialization voltage. The gate electrode of the fourth transistor ST4 may be connected to the third gate line GIL, the first electrode thereof may be connected to the third node N3, and the second electrode thereof may be connected to the first electrode of the fourth-first transistor ST4-1. The gate electrode of the fourth-first transistor ST4-1 may be connected to the third gate line GIL, the first electrode thereof may be connected to the second electrode of the fourth transistor ST4, and the second electrode thereof may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. In an embodiment, each first electrode of the fourth transistor ST4 and the fourth-first transistor ST4-1 may be a drain electrode and the second electrode thereof may be a source electrode, for example, but is not limited thereto.

The first and second pixels SP1 and SP2 share the fourth-first transistor ST4-1 connected between the fourth transistor ST4 and the first initialization voltage line VIL1, so that the leakage current characteristics of the fourth transistor ST4 may be improved and line defects or line shorts of the pixel circuit may be prevented by optimizing the design of the pixel circuit. The display device 10 may include a third transistor ST3 including a bias electrode and a fourth transistor ST4 connected in series with the fourth-first transistor ST4-1, so that the leakage current flowing through the third transistor ST3 and the fourth transistor ST4 may be minimized.

The fifth transistor ST5 may be turned on by an emission signal EMS of the emission control line EML to electrically connect the driving voltage line VDDL to the first node N1, which is the first electrode of the first transistor ST1. The gate electrode of the fifth transistor ST5 may be connected to the emission control line EML, the first electrode thereof may be connected to the driving voltage line VDDL, and the second electrode thereof may be connected to the first node N1. The second electrode of the fifth transistor ST5 may be electrically connected to the first electrode of the first transistor ST1 and the second electrode of the second transistor ST2 through the first node N1. In an embodiment, the first electrode of the fifth transistor ST5 may be a source electrode and the second electrode thereof may be a drain electrode, for example, but the disclosure is not limited thereto.

The sixth transistor ST6 may be turned on by the emission signal EMS of the emission control line EML to connect the second node N2, which is the second electrode of the first transistor ST1, to the fourth node N4, which is the first electrode of the light-emitting element ED. The gate electrode of the sixth transistor ST6 may be connected to the emission control line EML, the first electrode thereof may be connected to the second node N2, and the second electrode thereof may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light-emitting element ED and the first electrode of the seventh transistor ST7 through the fourth node N4. In an embodiment, the first electrode of the sixth transistor ST6 may be a source electrode and the second electrode thereof may be a drain electrode, for example, but the disclosure is not limited thereto.

When all of the fifth transistor ST5, the first transistor ST1, and the sixth transistor ST6 are turned on, the driving current Isd may be supplied to the light-emitting elements ED.

The seventh transistor ST7 may be turned on by a fourth gate signal GBS of the fourth gate line GBL to electrically connect the second initialization voltage line VIL2 to the fourth node N4 which is the first electrode of the light-emitting element ED. The seventh transistor ST7 may be turned based on the fourth gate signal GBS, thereby discharging the first electrode of the light-emitting element ED with a second initialization voltage. The gate electrode of the seventh transistor ST7 may be connected to the fourth gate line GBL, the first electrode thereof may be connected to the fourth node N4, and the second electrode thereof may be connected to the second initialization voltage line VIL2. The second electrode of the seventh transistor ST7 may be connected to the first electrode of the light-emitting element ED and the second electrode of the sixth transistor ST6 through the fourth node N4.

Each of the first transistor ST1, the second transistor ST2, the fifth transistor ST5, the sixth transistor ST6, and the seventh transistor ST7 may include a silicon-based semiconductor area. In an embodiment, each of the first transistor ST1, the second transistor ST2, the fifth transistor ST5, the sixth transistor ST6, and the seventh transistor ST7 may include a semiconductor area including low temperature polycrystalline silicon (“LTPS”), for example. The semiconductor area including LTPS may have relatively high electron mobility and substantially excellent turn-on characteristics. Accordingly, since the display device 10 includes the first transistor ST1, the second transistor ST2, the fifth transistor ST5, the sixth transistor ST6, and the seventh transistor ST7 having substantially excellent turn-on characteristics, a plurality of pixels SP may be driven stably and efficiently.

Each of the first transistor ST1, the second transistor ST2, the fifth transistor ST5, the sixth transistor ST6, and the seventh transistor ST7 may correspond to a p-type transistor. In an embodiment, each of the first transistor ST1, the second transistor ST2, the fifth transistor ST5, the sixth transistor ST6, and the seventh transistor ST7 may output a current flowing into the first electrode to the second electrode based on a gate low voltage applied to the gate electrode, for example.

Each of the third transistor ST3, the fourth transistor ST4, and the fourth-first transistor ST4-1 may include an oxide-based semiconductor area. In an embodiment, each of the third transistor ST3, the fourth transistor ST4, and the fourth-first transistor ST4-1 may have a coplanar structure in which the gate electrode is disposed on the oxide-based semiconductor area, for example. The transistor having a coplanar structure may have substantially excellent leakage current characteristics and perform relatively low frequency driving, thereby reducing power consumption. Accordingly, the display device 10 may include the third transistor ST3, the fourth transistor ST4, and the fourth-first transistor ST4-1 having substantially excellent leakage current characteristics, thereby preventing a leakage current from flowing in the pixel, and stably maintaining the voltage in the pixel.

Each of the third transistor ST3, the fourth transistor ST4, and the fourth-first transistor ST4-1 may correspond to an n-type transistor. In an embodiment, each of the third transistor ST3, the fourth transistor ST4, and the fourth-first transistor ST4-1 may output a current flowing into the first electrode to the second electrode based on a gate relatively high voltage applied to the gate electrode, for example.

The capacitor CST may be connected between the third node N3, which is the gate electrode of the first transistor ST1, and the driving voltage line VDDL. In an embodiment, the first capacitor electrode of the capacitor CST may be connected to the third node N3, and the second capacitor electrode of the capacitor CST may be connected to the driving voltage line VDDL, thereby maintaining a potential difference between the driving voltage line VDDL and the gate electrode of the first transistor ST1, for example.

Referring to FIG. 6 in conjunction with FIG. 5, the display device 10 may be driven through first to fifth periods t1 to t5 of one frame. The pixel SP may receive the first gate signal GWS, the second gate signal GCS, the third gate signal GIS, the fourth gate signal GBS, and the emission signal EMS.

The fourth transistor ST4 and the fourth-first transistor ST4-1 may receive the third gate signal GIS of a relatively high level during the first period t1 of one frame. The fourth transistor ST4 and the fourth-first transistor ST4-1 may be turned on based on the third gate signal GIS of a relatively high level to supply the first initialization voltage to the third node N3, which is the gate electrode of the first transistor ST1. Accordingly, the fourth transistor ST4 and the fourth-first transistor ST4-1 may initialize the gate electrode of the first transistor ST1 during the first period t1.

The seventh transistor ST7 may receive the fourth gate signal GBS of a relatively low level during the second period t2 of one frame. Here, the fourth gate signal GBS supplied to the pixels SP of the corresponding row may be the same as the first gate signal GWS supplied to the pixels SP of the previous row. The seventh transistor ST7 may be turned on based on the fourth gate signal GBS of a relatively low level to supply the second initialization voltage to the fourth node N4 that is the first electrode of the light-emitting element ED. Accordingly, the seventh transistor ST7 may initialize the first electrode of the light-emitting element ED during the second period t2.

The second transistor ST2 may receive the first gate signal GWS of a relatively low level during the third period t3. The second transistor ST2 may be turned on based on the first gate signal GWS of a relatively low level to supply a data voltage Vdata to the first node N1 that is the first electrode of the first transistor ST1.

The third transistor ST3 may receive the second gate signal GCS of a relatively high level during the fourth period t4. The third transistor ST3 may be turned on based on the second gate signal GCS of a relatively high level, and may electrically connect the second node N2 to the third node N3.

When the first electrode of the first transistor ST1 receives the data voltage Vdata, a source-gate voltage Vsg of the first transistor ST1 may correspond to a difference voltage (Vdata−VI1) between the data voltage Vdata and a first initialization voltage VI1, and the first transistor ST1 may be turned on because the source-gate voltage Vsg of the first transistor ST1 is greater than a threshold voltage Vth (Vdata−VI1>=Vth). Accordingly, at the moment when the first transistor ST1 is turned on in the third period t3, the source-drain current Isd of the first transistor ST1 may be determined according to the data voltage Vdata, the first initialization voltage VI1, and the threshold voltage Vth of the first transistor ST1 (Isd=k*(Vdata−VI1−Vth)\hat{ }2). The first transistor ST1 may supply the source-drain current Isd to the second node N2 until the source-gate voltage Vsg reaches the threshold voltage Vth of the first transistor ST1.

Further, the third transistor ST3 may be turned on for the fourth period t4 to supply the voltage of the second node N2 to the third node N3. In this manner, while the third transistor ST3 is turned on, the voltage of the third node N3 and the source-drain current Isd of the first transistor ST1 may be changed, and the voltage of the third node N3 may eventually converge to a difference voltage (Vdata-Vth) between the data voltage Vdata and the threshold voltage Vth of the first transistor ST1.

The emission signal EMS may have a gate low voltage during the fifth period t5. When the emission signal EMS has a relatively low level, the fifth and sixth transistors ST5 and ST6 may be turned on to supply the driving current Isd to the light-emitting element ED.

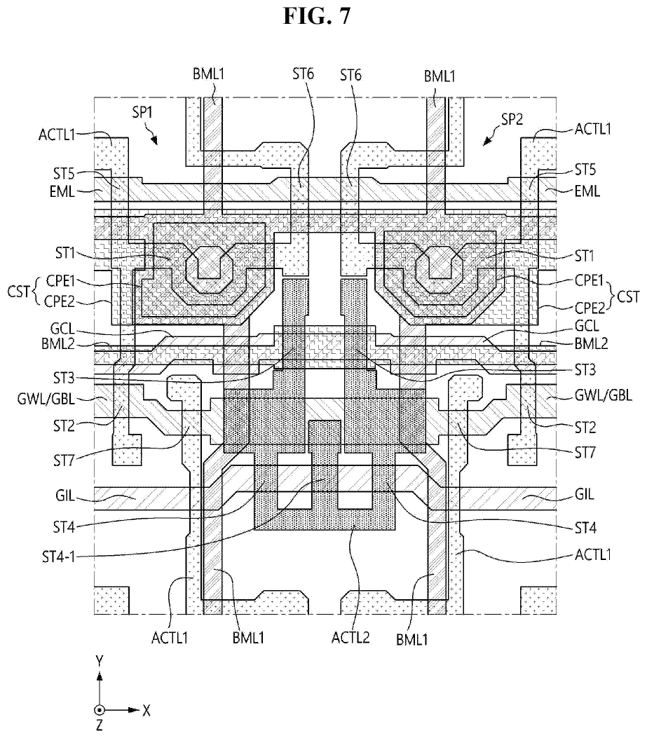

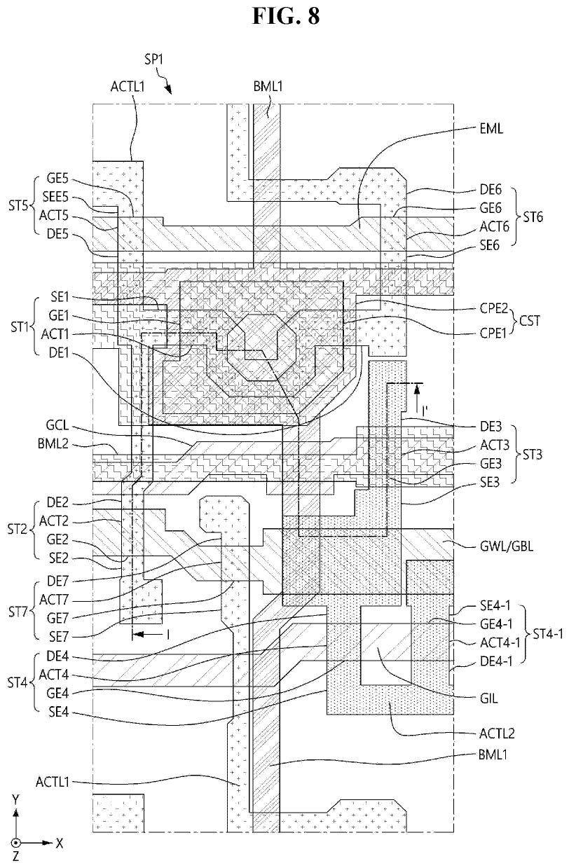

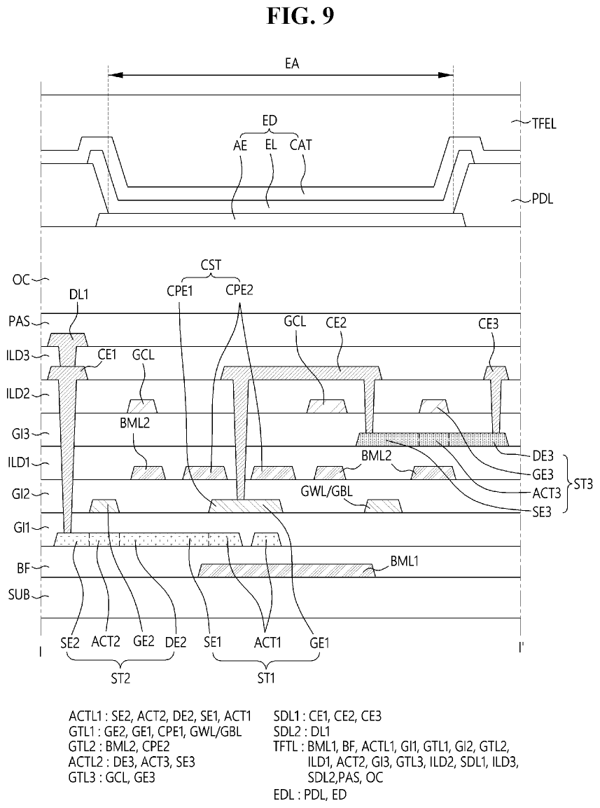

FIG. 7 is a layout diagram illustrating a first and second pixels of FIG. 5, FIG. 8 is a layout diagram illustrating a first pixel of FIG. 7, and FIG. 9 is a cross-sectional view taken along line I-I′ of FIG. 8. FIGS. 7 and 8 illustrate stacked structures of a first light-blocking layer BML1, a first active layer ACTL1, a first gate layer GTL1, a second gate layer GTL2, a second active layer ACTL2, and a third gate layer GTL3, and FIG. 9 further illustrates a stacked structure of a first source metal layer SDL1, a second source metal layer SDL2, and a light-emitting element ED.

Referring to FIGS. 7 to 9, each of the first pixel SP1 and the second pixel SP2 may include first to seventh transistors ST1, ST2, ST3, ST4, ST5, ST6, and ST7, a capacitor CST, and a light-emitting element ED. The first and second pixels SP1 and SP2 may share the fourth-first transistor ST4-1.

The first transistor ST1 may include a semiconductor area ACT1, a gate electrode GE1, a first electrode SE1, and a second electrode DE1. The semiconductor area ACT1, the first electrode SE1, and the second electrode DE1 of the first transistor ST1 may be disposed in the first active layer ACTL1, and the gate electrode GE1 of the first transistor ST1 may be disposed in the first gate layer GTL1. The gate electrode GE1 of the first transistor ST1 may be a part of a first capacitor electrode CPE1 of the first gate layer GTL1 and overlap the semiconductor area ACT1 of the first transistor ST1. In an embodiment, the semiconductor area ACT1 of the first transistor ST1 may include LTPS, for example.

The gate electrode GE1 of the first transistor ST1 may be electrically connected to a second electrode SE3 of the third transistor ST3 and a first electrode DE4 of the fourth transistor ST4 through a second connection electrode CE2 of the first source metal layer SDL1. The first electrode SE1 of the first transistor ST1 may be connected to a second electrode DE2 of the second transistor ST2 and a second electrode DE5 of the fifth transistor ST5. The second electrode DE1 of the first transistor ST1 may be connected to a first electrode DE3 of the third transistor ST3 and a first electrode SE6 of the sixth transistor ST6. The second electrode DE1 of the first transistor ST1 may be connected to the first electrode SE6 of the sixth transistor ST6 disposed in the first active layer ACTL1 and may be electrically connected to the first electrode DE3 of the third transistor ST3 disposed in the second active layer ACTL2.

The second transistor ST2 may include a semiconductor area ACT2, a gate electrode GE2, a first electrode SE2, and the second electrode DE2. The semiconductor area ACT2, the first electrode SE2, and the second electrode DE2 of the second transistor ST2 may be disposed in the first active layer ACTL1, and the gate electrode GE2 of the second transistor ST2 may be disposed in the first gate layer GTL1. The gate electrode GE2 of the second transistor ST2 may be a part of the first gate line GWL of the first gate layer GTL1 and overlap the semiconductor area ACT2 of the second transistor ST2. In an embodiment, the semiconductor area ACT2 of the second transistor ST2 may include LTPS, for example.

The first electrode SE2 of the second transistor ST2 may be electrically connected to the first data line DL1 of the second source metal layer SDL2 through the first connection electrode CE1 of the first source metal layer SDL1. The second electrode DE2 of the second transistor ST2 may be connected to the first electrode SE1 of the first transistor ST1 and the second electrode DE5 of the fifth transistor ST5.

The third transistor ST3 may include a semiconductor area ACT3, a gate electrode GE3, a first electrode DE3, and a second electrode SE3. The semiconductor area ACT3, the first electrode DE3, and the second electrode SE3 of the third transistor ST3 may be disposed in the second active layer ACTL2, and the gate electrode GE3 of the third transistor ST3 may be disposed in the third gate layer GTL3. The gate electrode GE3 of the third transistor ST3 may be a part of the second gate line GCL of the third gate layer GTL3 and overlap the semiconductor area ACT3 of the third transistor ST3. In an embodiment, the semiconductor area ACT3 of the third transistor ST3 may include oxide, for example.

The first electrode DE3 of the third transistor ST3 may be electrically connected to the second electrode DE1 of the first transistor ST1 disposed in the first active layer ACTL1 and the first electrode SE6 of the sixth transistor ST6 through a third connection electrode CE3 of the first source metal layer SDL1. The second electrode SE3 of the third transistor ST3 may be connected to a first electrode DE4 of the fourth transistor ST4 disposed in the second active layer ACTL2. The second electrode SE3 of the third transistor ST3 may be electrically connected to the gate electrode GE1 of the first transistor ST1 through the second connection electrode CE2.

The fourth transistor ST4 may include a semiconductor area ACT4, a gate electrode GE4, the first electrode DE4, and a second electrode SE4. The semiconductor area ACT4, the first electrode DE4, and the second electrode SE4 of the fourth transistor ST4 may be disposed in the second active layer ACTL2, and the gate electrode GE4 of the fourth transistor ST4 may be disposed in the third gate layer GTL3. The gate electrode GE4 of the fourth transistor ST4 may be a part of the third gate line GIL of the third gate layer GTL3 and overlap the semiconductor area ACT4 of the fourth transistor ST4. In an embodiment, the semiconductor area ACT4 of the fourth transistor ST4 may include oxide, for example.

The first electrode DE4 of the fourth transistor ST4 may be connected to the second electrode SE3 of the third transistor ST3 and may be electrically connected to the gate electrode GE1 of the first transistor ST1. The second electrode SE4 of the fourth transistor ST4 may be connected to a first electrode DE4-1 of the fourth-first transistor ST4-1 disposed in the second active layer ACTL2.

The fourth-first transistor ST4-1 may include a semiconductor area ACT4-1, a gate electrode GE4-1, the first electrode DE4-1, and a second electrode SE4-1. The semiconductor area ACT4-1, the first electrode DE4-1, and the second electrode SE4-1 of the fourth-first transistor ST4-1 may be disposed in the second active layer ACTL2, and the gate electrode GE4-1 of the fourth-first transistor ST4-1 may be disposed in the third gate layer GTL3. The gate electrode GE4-1 of the fourth-first transistor ST4-1 may be a part of the third gate line GIL and overlap the semiconductor area ACT4-1 of the fourth-first transistor ST4-1. In an embodiment, the semiconductor area ACT4-1 of the fourth-first transistor ST4-1 may include oxide, for example.

The first electrode DE4-1 of the fourth-first transistor ST4-1 may be connected to the second electrode SE4 of the fourth transistor ST4. The second electrode SE4-1 of the fourth-first transistor ST4-1 may be electrically connected to the first initialization voltage line VIL1. The first initialization voltage line VIL1 may be disposed in the second source metal layer SDL2, but is not limited thereto.

The third gate line GIL may not overlap the second gate layer GTL2. The display device 10 may include the fourth transistor ST4 and the fourth-first transistor ST4-1 and may be designed so that the second gate layer GTL2 does not overlap the third gate line GIL, thereby reducing a line connection portion and the overlapping portion to reduce the line defect rate.

The fifth transistor ST5 may include a semiconductor area ACT5, a gate electrode GE5, a first electrode SE5, and the second electrode DE5. The semiconductor area ACT5, the first electrode SE5, and the second electrode DE5 of the fifth transistor ST5 may be disposed in the first active layer ACTL1, and the gate electrode GE5 of the fifth transistor ST5 may be disposed in the first gate layer GTL1. The gate electrode GE5 of the fifth transistor ST5 may be a part of the emission control line EML of the first gate layer GTL1 and overlap the semiconductor area ACT5 of the fifth transistor ST5. In an embodiment, the semiconductor area ACT5 of the fifth transistor ST5 may include LTPS, for example.

The first electrode SE5 of the fifth transistor ST5 may be electrically connected to the driving voltage line VDDL. In an embodiment, the driving voltage line VDDL may be disposed in the second source metal layer SDL2, for example, but is not limited thereto. The second electrode DE5 of the fifth transistor ST5 may be connected to the first electrode SE1 of the first transistor ST1 and the second electrode DE2 of the second transistor ST2.

The sixth transistor ST6 may include a semiconductor area ACT6, a gate electrode GE6, the first electrode SE6, and a second electrode DE6. The semiconductor area ACT6, the first electrode SE6, and the second electrode DE6 of the sixth transistor ST6 may be disposed in the first active layer ACTL1, and the gate electrode GE6 of the sixth transistor ST6 may be disposed in the first gate layer GTL1. The gate electrode GE6 of the sixth transistor ST6 may be a part of the emission control line EML and overlap the semiconductor area ACT6 of the sixth transistor ST6. In an embodiment, the semiconductor area ACT6 of the sixth transistor ST6 may include LTPS, for example.

The first electrode SE6 of the sixth transistor ST6 may be connected to the second electrode DE1 of the first transistor ST1 and electrically connected to the first electrode DE3 of the third transistor ST3. The second electrode DE6 of the sixth transistor ST6 may be connected to the first electrode SE7 of the seventh transistor ST7 disposed in the first active layer ACTL1, and electrically connected to the first electrode of the light-emitting element ED.

The seventh transistor ST7 may include a semiconductor area ACT7, a gate electrode GE7, a first electrode SE7, and a second electrode DE7. The semiconductor area ACT7, the first electrode SE7, and the second electrode DE7 of the seventh transistor ST7 may be disposed in the first active layer ACTL1, and the gate electrode GE7 of the seventh transistor ST7 may be disposed in the first gate layer GTL1. The gate electrode GE7 of the seventh transistor ST7 may be a part of the fourth gate line GBL and overlap the semiconductor area ACT7 of the seventh transistor ST7. In an embodiment, the semiconductor area ACT7 of the seventh transistor ST7 may include LTPS, for example.

The first electrode SE7 of the seventh transistor ST7 may be connected to the second electrode DE6 of the sixth transistor ST6 and electrically connected to the first electrode of the light-emitting element ED. The second electrode DE7 of the seventh transistor ST7 may be electrically connected to the second initialization voltage line VIL2. In an embodiment, the second initialization voltage line VIL2 may be disposed in the second source metal layer SDL2, for example, but is not limited thereto.

The capacitor CST may include the first capacitor electrode CPE1 and a second capacitor electrode CPE2. The first and second capacitor electrodes CPE1 and CPE2 may overlap each other. The first capacitor electrode CPE1 of the capacitor CST may be disposed in the first gate layer GTL1, and the second capacitor electrode CPE2 may be disposed in the second gate layer GTL2. The first capacitor electrode CPE1 of the capacitor CST may include the gate electrode GE1 of the first transistor ST1, and the second capacitor electrode CPE2 may be electrically connected to the driving voltage line VDDL.

In FIG. 9, the display panel 100 may include a substrate SUB, a thin film transistor layer TFTL, a light-emitting element layer EDL, and an encapsulation layer TFEL.

The substrate SUB may be a base substrate or a base member. The substrate SUB may be a flexible substrate which may be bent, folded or rolled. In an embodiment, the substrate SUB may include a polymer resin such as polyimide (“PI”), for example, but is not limited thereto. In another embodiment, the substrate SUB may include a glass material or a metal material.

The thin film transistor layer TFTL may include a first metal layer BML1, a buffer layer BF, the first active layer ACTL1, a first gate insulating layer GI1, the first gate layer GTL1, a second gate insulating layer GI2, the second gate layer GTL2, a first inter-insulating layer ILD1, a second active layer ACT2, a third gate insulating layer GI3, the third gate layer GTL3, a second inter-insulating layer ILD2, the first source metal layer SDL1, a third inter-insulating layer ILD3, the second source metal layer SDL2, a passivation layer PAS, and a planarization layer OC.

The first metal layer BML1 may be disposed on the substrate SUB. The first metal layer BML1 may overlap the capacitor CST. In an embodiment, the first metal layer BML1 overlapping the capacitor CST of each of the plurality of pixels SP may be connected to each other, for example, but is not limited thereto. The first metal layer BML1 may include a light-blocking material.

The buffer layer BF may be disposed on the first metal layer BML1. In an embodiment, the buffer layer BF may include an inorganic layer of capable of preventing permeation of air or moisture, for example. In an embodiment, the buffer layer BF may include a plurality of inorganic layers alternately stacked, for example.

The first active layer ACTL1 may be disposed on the buffer layer BF. The first active layer ACTL1 may include a silicon-based material. In an embodiment, the first active layer ACTL1 may include or consist of LTPS, for example. The first active layer ACTL1 may include the respective semiconductor areas ACT1, ACT2, ACT5, ACT6, and ACT7, the respective first electrodes SE1, SE2, SE5, SE6, and SE7, and the respective second electrodes DE1, DE2, DE5, DE6, and DE7 of the first transistor ST1, the second transistor ST2, the fifth transistor ST5, a sixth transistor ST6, and a seventh transistor ST7.

The first gate insulating layer GI1 may be disposed on the first active layer ACTL1. The first gate insulating layer GI1 may insulate the first active layer ACTL1 from the first gate layer GTL1.

The first gate layer GTL1 may be disposed on the first gate insulating layer GI1. The first gate layer GTL1 may include the first and fourth gate lines GWL and GBL, an emission control line EML, a first capacitor electrode CPE1, and the respective gate electrodes GE1, GE2, GE5, GE6, and GE7 of the first transistor ST1, the second transistor ST2, the fifth transistor ST5, the sixth transistor ST6, and the seventh transistor ST7.

The second gate insulating layer GI2 may be disposed on the first gate layer GTL1. The second gate insulating layer GI2 may insulate the first gate layer GTL1 from the second gate layer GTL2.

The second gate layer GTL2 may be disposed on the second gate insulating layer GI2. The second gate layer GTL2 may include a second capacitor electrode CPE2 and a second metal layer BML2. The second metal layer BML2 may overlap the second gate line GCL. The second metal layer BML2 may include a light-blocking material. The second metal layer BML2 may be disposed under the third transistor ST3 to block light incident on the third transistor ST3. The second metal layer BML2 may include a bias electrode of the third transistor ST3. The bias electrode of the third transistor ST3 may overlap the semiconductor area ACT3 of the third transistor ST3. The bias electrode of the third transistor ST3 may be electrically connected to the gate electrode GE3 of the third transistor ST3. The bias electrode of the third transistor ST3 may improve leakage current characteristics, thereby stabilizing the electric field of the third transistor ST3 and improving output characteristics.

The first inter-insulating layer ILD1 may be disposed on the second gate layer GTL2. The first inter-insulating layer ILD1 may insulate the second gate layer GTL2 from the second active layer ACTL2.

The second active layer ACTL2 may be disposed on the first inter-insulating layer ILD1. The second active layer ACTL2 may include an oxide-based material. The second active layer ACTL2 may include the respective semiconductor areas ACT3, ACT4, and ACT4-1, the respective first electrode DE3, DE4, and DE4-1, and the respective second electrodes SE3, SE4, SE4-1 of the third transistor ST3, the fourth transistor ST4, and the fourth-first transistor ST4-1.

The third gate insulating layer GI3 may be disposed on the second active layer ACTL2. The third gate insulating layer GI3 may insulate the second active layer ACTL2 from the third gate layer GTL3.

The third gate layer GTL3 may be disposed on the third gate insulating layer GI3. The third gate layer GTL3 may include second and third gate lines GCL and GIL and the respective gate electrodes GE3, GE4, and GE4-1 of the third transistor ST3, the fourth transistor ST4, and the fourth-first transistor ST4-1.

The second inter-insulating layer ILD2 may be disposed on the third gate layer GTL3. The second inter-insulating layer ILD2 may insulate the third gate layer GTL3 from the first source metal layer SDL1.

The first source metal layer SDL1 may be disposed on the second inter-insulating layer ILD2. The first source metal layer SDL1 may include first to third connection electrodes CE1, CE2, and CE3.

The third inter-insulating layer ILD3 may be disposed on the first source metal layer SDL1. The third inter-insulating layer ILD3 may insulate the first source metal layer SDL1 from the second source metal layer SDL2.

The second source metal layer SDL2 may be disposed on the third inter-insulating layer ILD3. The second source metal layer SDL2 may include the first data line DL1. Although not shown in FIGS. 7 to 9, the driving voltage line VDDL, the first initialization voltage line VIL1, the second initialization voltage line VIL2, and the relatively low potential line VSSL may be disposed in the second source metal layer SDL2.

The passivation layer PAS may be disposed on the second source metal layer SDL2. The passivation layer PAS may protect pixel circuits of the pixels SP.

The planarization layer OC may be disposed on the passivation layer PAS. The planarization layer OC may planarize the upper end of the thin film transistor layer TFTL. The planarization layer OC may include an organic insulating material such as polyimide (“PI”).

The light-emitting element layer EDL may include a pixel defining layer PDL and a light-emitting element ED. The light-emitting element ED may include a first electrode AE, a light-emitting layer EL, and a second electrode CAT.

The pixel defining layer PDL may be disposed on the planarization layer OC. The pixel defining layer PDL may define a plurality of emission areas EA. The pixel defining layer PDL may include an organic insulating material such as polyimide (“PI”).

The first electrode AE may be disposed on the planarization layer OC. The first electrode AE may overlap one of the plurality of emission areas EA defined by the pixel defining layer PDL. The first electrode AE may receive a driving current from the pixel circuit of the pixel SP.

The light-emitting layer EL may be disposed on the first electrode AE. In an embodiment, the light-emitting layer EL may be an organic light-emitting layer including an organic material, for example, but is not limited thereto. In the case where the light-emitting layer EL is the organic light-emitting layer, when the pixel circuit of the pixel SP applies a predetermined voltage to the first electrode AE, and the second electrode CAT receives the common voltage or a cathode voltage, holes and electrons may move to the organic light-emitting layer EL through a hole transport layer and a electron transport layer, respectively, and the holes and electrons may combine with each other in the organic light-emitting layer EL to emit light.

The second electrode CAT may be disposed on the light-emitting layer EL. In an embodiment, the second electrode CAT may not be divided for each of the pixels SP, but may be formed as an electrode body common to all pixels SP, for example. The second electrode CAT may be disposed on the light-emitting layer EL in the plurality of emission areas EA, and may be disposed on the pixel defining layer PDL in an area other than the plurality of emission areas.

The encapsulation layer TFEL may be disposed on the second electrode CAT to cover the plurality of light-emitting elements ED. The encapsulation layer TFEL may include at least one inorganic layer to prevent oxygen or moisture from permeating into the plurality of light-emitting elements ED. The encapsulation layer TFEL may include at least one organic layer to protect the plurality of light-emitting elements ED from foreign matters such as dust.

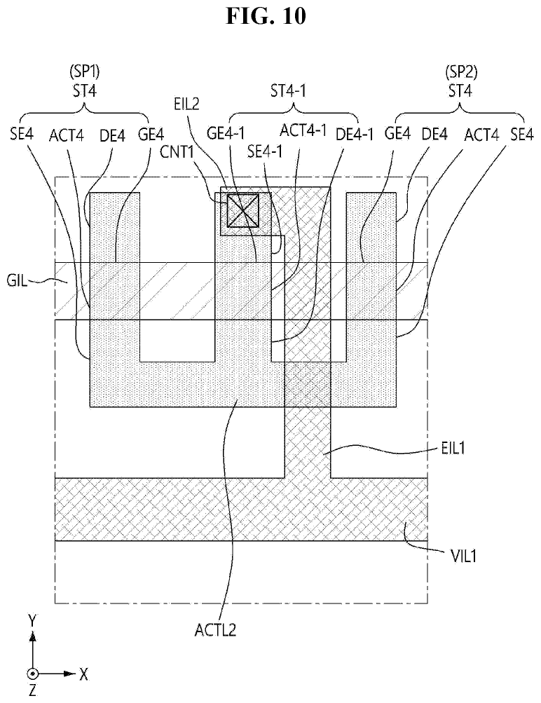

FIG. 10 is a plan view illustrating an embodiment of a first initialization voltage line in a display device.

Referring to FIG. 10, the second active layer ACTL2 may include the respective semiconductor areas ACT3, ACT4, and ACT4-1, the respective first electrodes DE3, DE4, and DE4-1, and respective the second electrodes SE3, SE4, and SE4-1 of the third transistor ST3, the fourth transistor ST4, and the fourth-first transistor ST4-1.

The third gate layer GTL3 may be disposed on the second active layer ACTL2. The third gate layer GTL3 may include the third gate line GIL, and the respective gate electrodes GE3, GE4, and GE4-1 of the third transistor ST3, the fourth transistor ST4, and the fourth-first transistor ST4-1.

The second source metal layer SDL2 may be disposed on the third gate layer GTL3. The second source metal layer SDL2 may include a first initialization voltage line VIL1. The first initialization voltage line VIL1 may extend in the X-axis direction. The first initialization voltage line VIL1 may include first and second extension portions EIL1 and EIL2.

The first extension portion EIL1 of the first initialization voltage line VIL1 may extend from the first initialization voltage line VIL1 in the Y-axis direction. The first extension portion EIL1 may cross the second active layer ACTL2 and the third gate line GIL. The first extension portion EIL1 may not overlap the respective semiconductor areas ACT3, ACT4, and ACT4-1 of the third transistor ST3, the fourth transistor ST4, and the fourth-first transistor ST4-1.

The second extension portion EIL2 of the first initialization voltage line VIL1 may extend from the first extension portion EIL1 in the opposite direction of the X-axis direction. The second extension portion EIL2 may be connected to the second electrode SE4-1 of the fourth-first transistor ST4-1 through a first contact hole CNT1. The first contact hole CNT1 may pass through the third inter-insulating layer ILD3, the second inter-insulating layer ILD2, and the third gate insulating layer GI3 of FIG. 9. Accordingly, the first initialization voltage line VIL1 may be electrically connected to the second electrode SE4-1 of the fourth-first transistor ST4-1 through the first and second extension portions EIL1 and EIL2.

The third gate line GIL may not overlap the second gate layer GTL2. The display device 10 may include the fourth transistor ST4 and the fourth-first transistor ST4-1 and may be designed so that the second gate layer GTL2 does not overlap the third gate line GIL, thereby reducing the line connection portion and the overlapping portion to reduce the line defect rate.

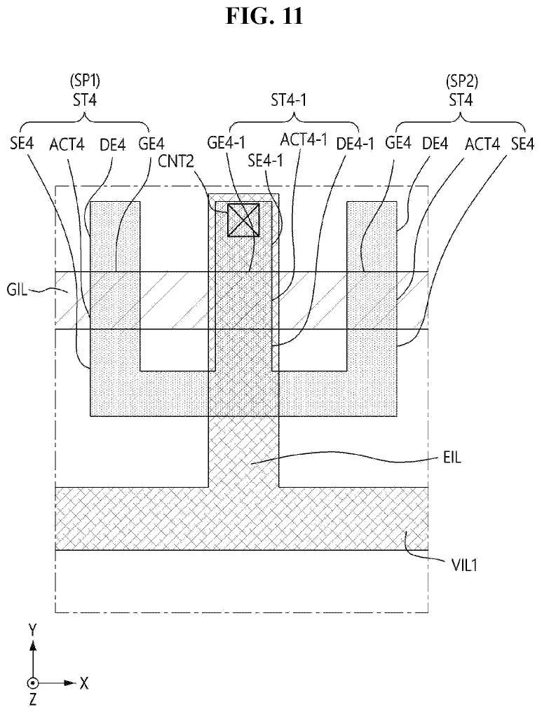

FIG. 11 is a plan view of another embodiment of a first initialization voltage line in a display device.

Referring to FIG. 11, the second active layer ACTL2 may include the respective semiconductor areas ACT3, ACT4, and ACT4-1, the respective first electrodes DE3, DE4, and DE4-1, and the respective second electrodes SE3, SE4, and SE4-1 of the third transistor ST3, the fourth transistor ST4, and the fourth-first transistor ST4-1.

The third gate layer GTL3 may be disposed on the second active layer ACTL2. The third gate layer GTL3 may include the third gate line GIL, and the respective gate electrodes GE3, GE4, and GE4-1 of the third transistor ST3, the fourth transistor ST4, and the fourth-first transistor ST4-1.

The second source metal layer SDL2 may be disposed on the third gate layer GTL3. The second source metal layer SDL2 may include the first initialization voltage line VIL1. The first initialization voltage line VIL1 may extend in the X-axis direction. The first initialization voltage line VIL1 may include an extension portion EIL.

The extension portion EIL of the first initialization voltage line VIL1 may extend from the first initialization voltage line VIL1 in the Y-axis direction. The extension portion EIL may cross the third gate line GIL. The extension portion EIL may overlap the semiconductor area ACT4-1, the gate electrode GE4-1, the first electrode DE4-1, and the second electrode SE4-1 of the fourth-first transistor ST4-1. The extension portion EIL may be connected to the second electrode SE4-1 of the fourth-first transistor ST4-1 through a second contact hole CNT2. The second contact hole CNT2 may pass through the third inter-insulating layer ILD3, the second inter-insulating layer ILD2, and the third gate insulating layer GI3 of FIG. 9. Accordingly, the first initialization voltage line VIL1 may be electrically connected to the second electrode SE4-1 of the fourth-first transistor ST4-1 through the extension portions EIL.

The third gate line GIL may not overlap the second gate layer GTL2. The display device 10 may include the fourth transistor ST4 and the fourth-first transistor ST4-1 and may be designed so that the second gate layer GTL2 does not overlap the third gate line GIL, thereby reducing the line connection portion and the overlapping portion to reduce the line defect rate.

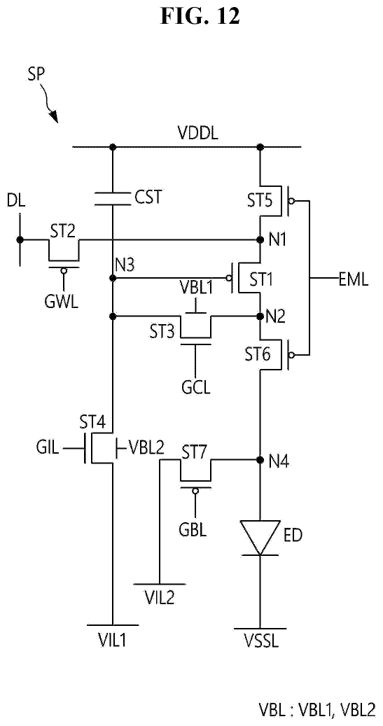

FIG. 12 is a circuit diagram illustrating a pixel of a display device.

Referring to FIG. 12, the pixel SP may be connected to the first gate line GWL, the second gate line GCL, the third gate line GIL, the fourth gate line GBL, the emission control line EML, the data line DL, the driving voltage line VDDL, a first initialization voltage line VIL1, the second initialization voltage line VIL2, a first bias voltage line VBL1, a second bias voltage line VBL2, and the relatively low potential line VSSL.

The pixel SP may include a light-emitting element ED and a pixel circuit driving the light-emitting element ED. The pixel circuit may include a plurality of switching elements and a capacitor CST. The plurality of switching elements may include first to seventh transistors ST1, ST2, ST3, ST4, ST5, ST6, and ST7.

The first transistor ST1 may control a driving current supplied to the light-emitting element ED. The first transistor ST1 may include a gate electrode, a first electrode, and a second electrode. The gate electrode of the first transistor ST1 may be connected to a third node N3, the first electrode thereof may be connected to a first node N1, and the second electrode thereof may be connected to a second node N2. In an embodiment, the first electrode of the first transistor ST1 may be a source electrode and the second electrode thereof may be a drain electrode, for example, but the disclosure is not limited thereto.

The first transistor ST1 may control a source-drain current Isd (hereinafter, also referred to as “driving current”) according to the data voltage applied to the gate electrode. The driving current Isd flowing through the channel of the first transistor ST1 may be proportional to the square of a difference between a threshold voltage Vth and a voltage Vsg between the source electrode and the gate electrode of the first transistor ST1 (Isd=k×(Vsg−Vth)²). Here, k denotes a proportional coefficient determined by the structure and physical characteristics of the first transistor ST1, Vsg denotes a source-gate voltage of the first transistor ST1, and Vth denotes a threshold voltage of the first transistor ST1.

The light-emitting element ED may emit light by receiving the driving current ISD. The emission amount or the luminance of the light-emitting element ED may be proportional to the magnitude of the driving current Isd. The light-emitting element ED may include a first electrode, a second electrode, and a light-emitting layer disposed between the first electrode and the second electrode. The first electrode of the light-emitting element ED may be connected to the fourth node N4. The first electrode of the light-emitting element ED may be connected to the second electrode of the sixth transistor ST6 and the second electrode of the seventh transistor ST7 through the fourth node N4. In an embodiment, the first electrode of the light-emitting element ED may be an anode electrode or a pixel electrode, and the second electrode thereof may be a cathode electrode or a common electrode, for example, but the disclosure is not limited thereto.

The second transistor ST2 may be turned on by a first gate signal of the first gate line GWL to electrically connect the data line DL to the first node N1 which is the first electrode of the first transistor ST1. The second transistor ST2 may be turned on based on the first gate signal to supply the data voltage to the first node N1. The gate electrode of the second transistor ST2 may be connected to the first gate line GWL, the first electrode thereof may be connected to the data line DL, and the second electrode thereof may be connected to the first node N1. The second electrode of the second transistor ST2 may be connected to the first electrode of the first transistor ST1 and the second electrode of the fifth transistor ST5 through the first node N1. In an embodiment, the first electrode of the second transistor ST2 may be a source electrode and the second electrode thereof may be a drain electrode, for example, but the disclosure is not limited thereto.

The third transistor ST3 may be turned on by a second gate signal of the second gate line GCL to electrically connect the second node N2, which is the second electrode of the first transistor ST1, to the third node N3, which is the gate electrode of the first transistor ST1. The gate electrode of the third transistor ST3 may be connected to the second gate line GCL, the first electrode thereof may be connected to the second node N2, and the second electrode thereof may be connected to the third node N3. The first electrode of the third transistor ST3 may be connected to the second electrode of the first transistor ST1 and the first electrode of the sixth transistor ST6 through the second node N2. The second electrode of the third transistor ST3 may be connected to the gate electrode of the first transistor ST1, the first electrode of the fourth transistor ST4, and a first capacitor electrode of a capacitor CST through the third node N3. In an embodiment, the first electrode of the third transistor ST3 may be a drain electrode and the second electrode thereof may be a source electrode, for example, but is not limited thereto.

The third transistor ST3 may include a bias electrode. The bias electrode of the third transistor ST3 may overlap the semiconductor area of the third transistor ST3. The bias electrode of the third transistor ST3 may be electrically connected to a first bias voltage line VBL1, and receive a first bias voltage from the first bias voltage line VBL1. The bias electrode of the third transistor ST3 may improve leakage current characteristics, thereby stabilizing the electric field of the third transistor ST3 and improving output characteristics.

The fourth transistor ST4 may be turned on by a third gate signal of the third gate line GIL to electrically connect the first initialization voltage line VIL1 to the third node N3, which is the gate electrode of the first transistor ST1. The fourth transistor ST4 may be turned on based on by the third gate signal, thereby discharging the gate electrode of the first transistor ST1 with a first initialization voltage. The gate electrode of the fourth transistor ST4 may be connected to the third gate line GIL, the first electrode thereof may be connected to the third node N3, and the second electrode thereof may be connected to the first initialization voltage line VIL1. The first electrode of the fourth transistor ST4 may be connected to the gate electrode of the first transistor ST1, the second electrode of the third transistor ST3, and the first capacitor electrode of the capacitor CST through the third node N3. In an embodiment, the first electrode of the fourth transistor ST4 may be a drain electrode and the second electrode thereof may be a source electrode, for example, but is not limited thereto.

The fourth transistor ST4 may include a bias electrode. The bias electrode of the fourth transistor ST4 may overlap the semiconductor area of the fourth transistor ST4. The bias electrode of the fourth transistor ST4 may be electrically connected to a second bias voltage line VBL2, and receive a second bias voltage from the second bias voltage line VBL2. In an embodiment, the first bias voltage and the second bias voltage may be the same, for example. In another embodiment, the first bias voltage and the second bias voltage may be different from each other. The bias electrode of the fourth transistor ST4 may improve leakage current characteristics, thereby stabilizing the electric field of the fourth transistor ST4 and improving output characteristics.

The fifth transistor ST5 may be turned on by an emission signal of the emission control line EML to electrically connect the driving voltage line VDDL to the first node N1, which is the first electrode of the first transistor ST1. The gate electrode of the fifth transistor ST5 may be connected to the emission control line EML, the first electrode thereof may be connected to the driving voltage line VDDL, and the second electrode thereof may be connected to the first node N1. The second electrode of the fifth transistor ST5 may be electrically connected to the first electrode of the first transistor ST1 and the second electrode of the second transistor ST2 through the first node N1. In an embodiment, the first electrode of the fifth transistor ST5 may be a source electrode and the second electrode thereof may be a drain electrode, for example, but the disclosure is not limited thereto.

The sixth transistor ST6 may be turned on by the emission signal of the emission control line EML to connect the second node N2, which is the second electrode of the first transistor ST1, to the fourth node N4, which is the first electrode of the plurality of light-emitting elements ED. The gate electrode of the sixth transistor ST6 may be connected to the emission control line EML, the first electrode thereof may be connected to the second node N2, and the second electrode thereof may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light-emitting element ED and the first electrode of the seventh transistor ST7 through the fourth node N4. In an embodiment, the first electrode of the sixth transistor ST6 may be a source electrode and the second electrode thereof may be a drain electrode, for example, but the disclosure is not limited thereto.

When all of the fifth transistor ST5, the first transistor ST1, and the sixth transistor ST6 are turned on, the driving current Isd may be supplied to the plurality of light-emitting elements ED.

The seventh transistor ST7 may be turned on by a fourth gate signal of the fourth gate line GBL to electrically connect the second initialization voltage line VIL2 to the fourth node N4 which is the first electrode of the light-emitting element ED. The seventh transistor ST7 may be turned based on the fourth gate signal, thereby discharging the first electrode of the light-emitting element ED with a second initialization voltage. The gate electrode of the seventh transistor ST7 may be connected to the fourth gate line GBL, the first electrode thereof may be connected to the fourth node N4, and the second electrode thereof may be connected to the second initialization voltage line VIL2. The second electrode of the seventh transistor ST7 may be connected to the first electrode of the light-emitting element ED and the second electrode of the sixth transistor ST6 through the fourth node N4.

Each of the first transistor ST1, the second transistor ST2, the fifth transistor ST5, the sixth transistor ST6, and the seventh transistor ST7 may include a silicon-based semiconductor area. In an embodiment, each of the first transistor ST1, the second transistor ST2, the fifth transistor ST5, the sixth transistor ST6, and the seventh transistor ST7 may include a semiconductor area including LTPS, for example. The semiconductor area including or consisting of LTPS may have relatively high electron mobility and excellent turn-on characteristics. Accordingly, since the display device 10 includes the first transistor ST1, the second transistor ST2, the fifth transistor ST5, the sixth transistor ST6, and the seventh transistor ST7 having substantially excellent turn-on characteristics, a plurality of pixels SP may be driven stably and efficiently.

Each of the first transistor ST1, the second transistor ST2, the fifth transistor ST5, the sixth transistor ST6, and the seventh transistor ST7 may correspond to a p-type transistor. In an embodiment, each of the first transistor ST1, the second transistor ST2, the fifth transistor ST5, the sixth transistor ST6, and the seventh transistor ST7 may output a current flowing into the first electrode to the second electrode based on a gate low voltage applied to the gate electrode, for example.

Each of the third transistor ST3 and the fourth transistor ST4 may include an oxide-based semiconductor area. In an embodiment, each of the third transistor ST3 and the fourth transistor ST4 may have a coplanar structure in which the gate electrode is disposed on the oxide-based semiconductor area, for example. The transistor having a coplanar structure may have substantially excellent leakage current characteristics and perform relatively low frequency driving, thereby reducing power consumption. Accordingly, the display device 10 may include the third transistor ST3 and the fourth transistor ST4 having substantially excellent leakage current characteristics, thereby preventing a leakage current from flowing in the pixel, and stably maintaining the voltage in the pixel.

Each of the third transistor ST3 and the fourth transistor ST4 may correspond to an n-type transistor. In an embodiment, each of the third transistor ST3 and the fourth transistor ST4 may output a current flowing into the first electrode to the second electrode based on a gate relatively high voltage applied to the gate electrode, for example.

The capacitor CST may be connected between the third node N3, which is the gate electrode of the first transistor ST1, and the driving voltage line VDDL. In an embodiment, the first capacitor electrode of the capacitor CST may be connected to the third node N3, and the second capacitor electrode of the capacitor CST may be connected to the driving voltage line VDDL, thereby maintaining a potential difference between the driving voltage line VDDL and the gate electrode of the first transistor ST1, for example.

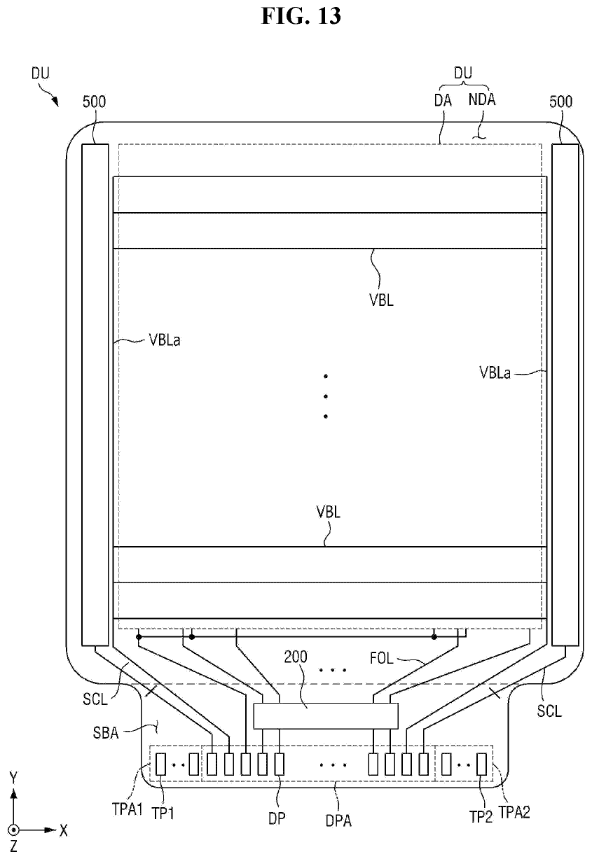

FIG. 13 is a plan view illustrating another embodiment of a bias voltage line of a display device. FIG. 13 is a view for illustrating an arrangement of the bias voltage line, and the same configuration as the above-described configuration will be described briefly, or a description thereof will be omitted.

Referring to FIG. 13, the display unit DU may include the display area DA and the non-display area NDA. The display area DA displays images therein and may be defined as a central area of the display panel 100. The non-display area NDA may surround the display area DA. The non-display area NDA may include the scan driver 500, fan-out lines FOL, and scan control lines SCL.

A bias voltage line VBL may include first and second bias voltage lines VBL1 and VBL2 of FIG. 12. The bias voltage lines VBL may extend in the X-axis direction and may be spaced apart from each other in the Y-axis direction. The bias voltage line VBL may be disposed across the display area DA. The bias voltage line VBL may be connected between a bias lead line VBLa disposed on the left side of the non-display area NDA and a bias lead line VBLa disposed on the right side of the non-display area NDA. The bias lead line VBLa may extend from the non-display area NDA to a display pad unit DP. Accordingly, the bias voltage line VBL may receive a bias voltage through the bias lead line VBLa and the display pad unit DP.

The display device 10 may easily control the bias voltage applied to the pixel SP by including the bias voltage line VBL electrically connected to the display pad unit DP. The display device 10 may supply a bias voltage different from the second gate signal of the second gate line GCL and the third gate signal of the third gate line GIL. Accordingly, by including a third transistor ST3 connected to the first bias voltage line VBL1 and a fourth transistor ST4 connected to the second bias voltage line VBL2, output characteristics may be improved by improving leakage current characteristics and stabilizing an electric field.

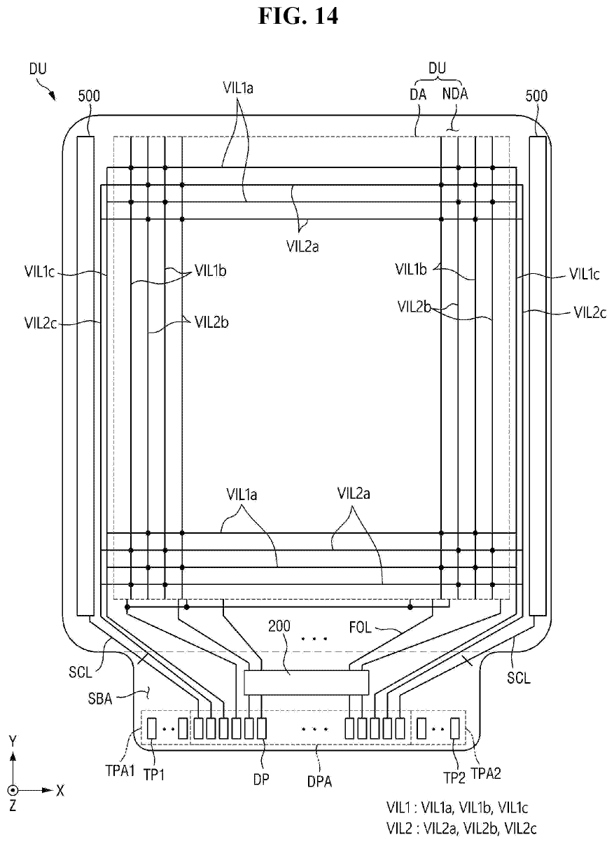

FIG. 14 is a plan view illustrating another embodiment of first and second initialization voltage lines of a display device.

Referring to FIG. 14, the display unit DU may include the display area DA and the non-display area NDA. The display area DA displays images therein and may be defined as a central area of the display panel 100. The non-display area NDA may surround the display area DA. The non-display area NDA may include the scan driver 500, fan-out lines FOL, and scan control lines SCL.

The first initialization voltage line VIL1 may include a horizontal portion VIL1a, a vertical portion VIL1b, and a lead portion VIL1c. The horizontal portion VIL1a of the first initialization voltage line VIL1 may extend in the X-axis direction and may be spaced apart from each other in the Y-axis direction. The horizontal portion VIL1a of the first initialization voltage line VIL1 may be disposed across the display area DA. The horizontal portion VIL1a of the first initialization voltage line VIL1 may be disposed between horizontal portions VIL2a of the second initialization voltage line VIL2. The horizontal portion VIL1a of the first initialization voltage line VIL1 may cross the vertical portion VIL2b of the second initialization voltage line VIL2. The horizontal portion VIL1a of the first initialization voltage line VIL1 may be connected between the lead portion VIL1c disposed on the left side of the non-display area NDA and the lead portion VIL1c disposed on the right side of the non-display area NDA.

The vertical portions VIL1b of the first initialization voltage line VIL1 may extend in the Y-axis direction and may be spaced apart from each other in the X-axis direction. The vertical portion VIL1b of the first initialization voltage line VIL1 may be disposed between vertical portions VIL2b of the second initialization voltage line VIL2. The vertical portion VIL1b of the first initialization voltage line VIL1 may be connected to the horizontal portion VIL1a of the first initialization voltage line VIL1. The vertical portion VIL1b of the first initialization voltage line VIL1 may cross a horizontal portion VIL2a of the second initialization voltage line VIL2. The vertical portion VIL1b of the first initialization voltage line VIL1 may supply the first initialization voltage received from the horizontal portion VIL1a to the pixel SP.

The lead portion VIL1c of the first initialization voltage line VIL1 may extend from the non-display area NDA to the display pad unit DP. Accordingly, the first initialization voltage line VIL1 may receive the first initialization voltage through the display pad unit DP.

The second initialization voltage line VIL2 may include the horizontal portion VIL2a, the vertical portion VIL2b, and a lead portion VIL2c. The horizontal portions VIL2a of the second initialization voltage line VIL2 may extend in the X-axis direction and may be spaced apart from each other in the Y-axis direction. The horizontal portion VIL2a of the second initialization voltage line VIL2 may be disposed across the display area DA. The horizontal portion VIL2a of the second initialization voltage line VIL2 may be disposed between the horizontal portions VIL1a of the first initialization voltage line VIL1. The horizontal portion VIL2a of the second initialization voltage line VIL2 may cross the vertical portion VIL1b of the first initialization voltage line VIL1. The horizontal portion VIL2a of the second initialization voltage line VIL2 may be connected between the lead portion VIL2c disposed on the left side of the non-display area NDA and the lead portion VIL2c disposed on the right side of the non-display area NDA.

The vertical portion VIL2b of the second initialization voltage line VIL2 may extend in the Y-axis direction and may be spaced apart from each other in the X-axis direction. The vertical portion VIL2b of the second initialization voltage line VIL2 may be disposed between the vertical portions VIL1b of the first initialization voltage line VIL1. The vertical portion VIL2b of the second initialization voltage line VIL2 may be connected to the horizontal portion VIL2a of the second initialization voltage line VIL2. The vertical portion VIL2b of the second initialization voltage line VIL2 may cross the horizontal portion VIL1a of the first initialization voltage line VIL1. The vertical portion VIL2b of the second initialization voltage line VIL2 may supply the second initialization voltage received from the horizontal portion VIL2a to the pixel SP.

The lead portion VIL2c of the second initialization voltage line VIL2 may extend from the non-display area NDA to the display pad unit DP. Accordingly, the second initialization voltage line VIL2 may receive the second initialization voltage through the display pad unit DP.

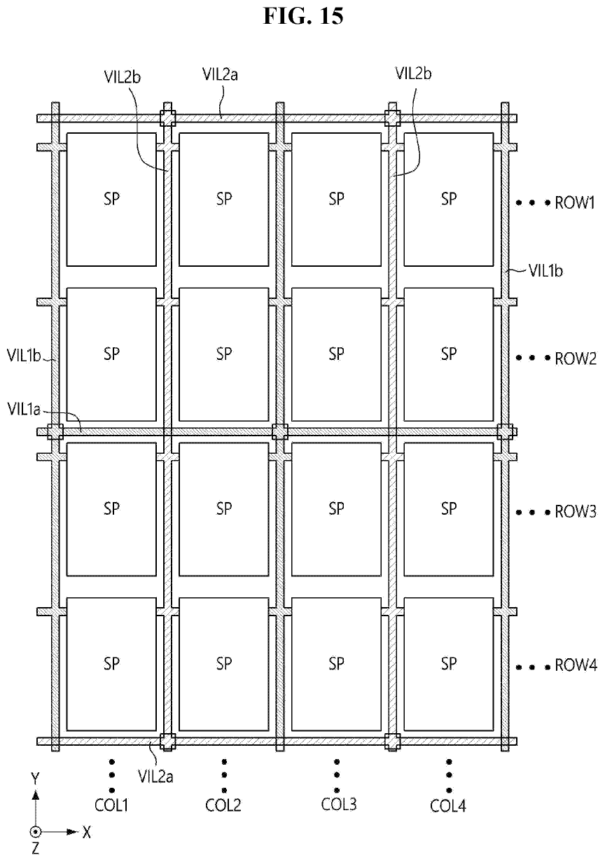

FIG. 15 is a diagram illustrating a connection relationship between a pixel and first and second initialization voltage lines in a display device of FIG. 14.

Referring to FIG. 15, pixels SP may be arranged along a plurality of rows and a plurality of columns. The horizontal portion VIL1a of the first initialization voltage line VIL1 may be disposed between the pixels SP arranged in a second row ROW2 and the pixels SP arranged in a third row ROW3. The vertical portion VIL1b of the first initialization voltage line VIL1 may be connected to the horizontal portion VIL1a of the first initialization voltage line VIL1. The vertical portion VIL1b of the first initialization voltage line VIL1 may be disposed on the left side of the pixels SP arranged in a first column COL1. The vertical portion VIL1b of the first initialization voltage line VIL1 may be disposed between the pixels SP arranged in a second column COL2 and the pixels SP arranged in a third column COL3. The vertical portion VIL1b of the first initialization voltage line VIL1 may be disposed on the right side of the pixels SP arranged in a fourth column COL4. The vertical portion VIL1b of the first initialization voltage line VIL1 may supply the first initialization voltage received from the horizontal portion VIL1a to the pixel SP.

The horizontal portion VIL2a of the second initialization voltage line VIL2 may be disposed above the pixels SP arranged in a first row ROW1. The horizontal portion VIL2a of the second initialization voltage line VIL2 may be disposed below the pixels SP arranged in a fourth row ROW4. The vertical portion VIL2b of the second initialization voltage line VIL2 may be connected to the horizontal portion VIL2a of the second initialization voltage line VIL2. The vertical portion VIL2b of the second initialization voltage line VIL2 may be disposed between the pixels SP arranged in the first column COL1 and the pixels SP arranged in the second column COL2. The vertical portion VIL2b of the second initialization voltage line VIL2 may be disposed between the pixels SP arranged in the third column COL3 and the pixels SP arranged in the fourth column COL4. The vertical portion VIL2b of the second initialization voltage line VIL2 may supply the second initialization voltage received from the horizontal portion VIL2a to the pixel SP.

The horizontal portion VIL1a of the first initialization voltage line VIL1 and the horizontal portion VIL2a of the second initialization voltage line VIL2 may not be disposed between the pixels SP arranged in the first row ROW1 and the pixels SP arranged in the second row ROW2. The horizontal portion VIL1a of the first initialization voltage line VIL1 and the horizontal portion VIL2a of the second initialization voltage line VIL2 may not be disposed between the pixels SP arranged in the third row ROW3 and the pixels SP arranged in the fourth row ROW4. Accordingly, in the display device 10, it is possible to design a relatively high resolution and reduce line defect rate by reducing the number of horizontal portions VIL1a and VIL2a of the first and second initialization voltage lines VIL1 and VIL2, respectively. Horizontal portions VIL1a and VIL2a of each of the first and second initialization voltage lines VIL1 and VIL2 may increase line width to reduce line resistance.

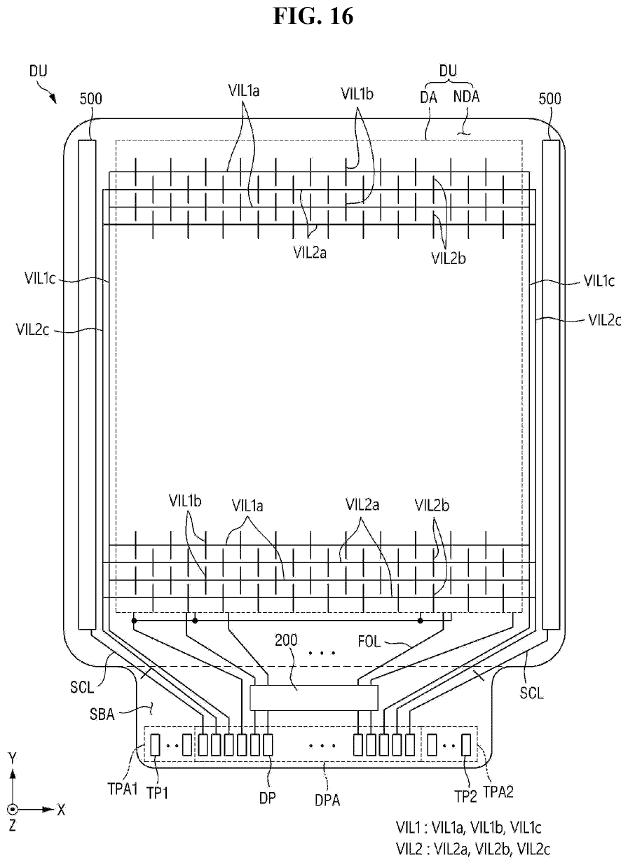

FIG. 16 is a plan view illustrating another embodiment of first and second initialization voltage lines of a display device.

Referring to FIG. 16, the display unit DU may include the display area DA and the non-display area NDA. The display area DA displays images therein and may be defined as a central area of the display panel 100. The non-display area NDA may surround the display area DA. The non-display area NDA may include the scan driver 500, fan-out lines FOL, and scan control lines SCL.

The first initialization voltage line VIL1 may include a horizontal portion VIL1a, a vertical portion VIL1b, and a lead portion VIL1c. The horizontal portion VIL1a of the first initialization voltage line VIL1 may extend in the X-axis direction and may be spaced apart from each other in the Y-axis direction. The horizontal portion VIL1a of the first initialization voltage line VIL1 may be disposed across the display area DA. The horizontal portion VIL1a of the first initialization voltage line VIL1 may be disposed between the horizontal portions VIL2a of the second initialization voltage line VIL2. The horizontal portion VIL1a of the first initialization voltage line VIL1 may be connected between the lead portion VIL1c disposed on the left side of the non-display area NDA and the lead portion VIL1c disposed on the right side of the non-display area NDA.

The vertical portion VIL1b of the first initialization voltage line VIL1 may be connected to the horizontal portion VIL1a of the first initialization voltage line VIL1. The vertical portion VIL1b of the first initialization voltage line VIL1 may extend from the horizontal portion VIL1a in the Y-axis direction and in the opposite direction to the Y-axis direction. The vertical portions VIL1b of the first initialization voltage line VIL1 may be spaced apart in the Y-axis direction with the horizontal portion VIL2a of the second initialization voltage line VIL2 interposed therebetween. The vertical portion VIL1b of the first initialization voltage line VIL1 may not cross the horizontal portion VIL2a of the second initialization voltage line VIL2. The vertical portion VIL1b of the first initialization voltage line VIL1 may be disposed between the vertical portions VIL2b of the second initialization voltage line VIL2. The vertical portion VIL1b of the first initialization voltage line VIL1 may supply the first initialization voltage received from the horizontal portion VIL1a to the pixel SP.

The lead portion VIL1c of the first initialization voltage line VIL1 may extend from the non-display area NDA to the display pad unit DP. Accordingly, the first initialization voltage line VIL1 may receive the first initialization voltage through the display pad unit DP.

The second initialization voltage line VIL2 may include a horizontal portion VIL2a, a vertical portion VIL2b, and a lead portion VIL2c. The horizontal portions VIL2a of the second initialization voltage line VIL2 may extend in the X-axis direction and may be spaced apart from each other in the Y-axis direction. The horizontal portion VIL2a of the second initialization voltage line VIL2 may be disposed across the display area DA. The horizontal portion VIL2a of the second initialization voltage line VIL2 may be disposed between the horizontal portions VIL1a of the first initialization voltage line VIL1. The horizontal portion VIL2a of the second initialization voltage line VIL2 may be connected between the lead portion VIL2c disposed on the left side of the non-display area NDA and the lead portion VIL2c disposed on the right side of the non-display area NDA.

The vertical portion VIL2b of the second initialization voltage line VIL2 may be connected to the horizontal portion VIL2a of the second initialization voltage line VIL2. The vertical portion VIL2b of the second initialization voltage line VIL2 may extend from the horizontal portion VIL2a in the Y-axis direction and in the opposite direction to the Y-axis direction. The vertical portions VIL2b of the second initialization voltage line VIL2 may be spaced apart in the Y-axis direction with the horizontal portion VIL1a of the first initialization voltage line VIL1 interposed therebetween. The vertical portion VIL2b of the second initialization voltage line VIL2 may not cross the horizontal portion VIL1a of the first initialization voltage line VIL1. The vertical portion VIL2b of the second initialization voltage line VIL2 may be disposed between the vertical portions VIL1b of the first initialization voltage line VIL1. The vertical portion VIL2b of the second initialization voltage line VIL2 may supply the second initialization voltage received from the horizontal portion VIL2a to the pixel SP.

The lead portion VIL2c of the second initialization voltage line VIL2 may extend from the non-display area NDA to the display pad unit DP. Accordingly, the second initialization voltage line VIL2 may receive the second initialization voltage through the display pad unit DP.

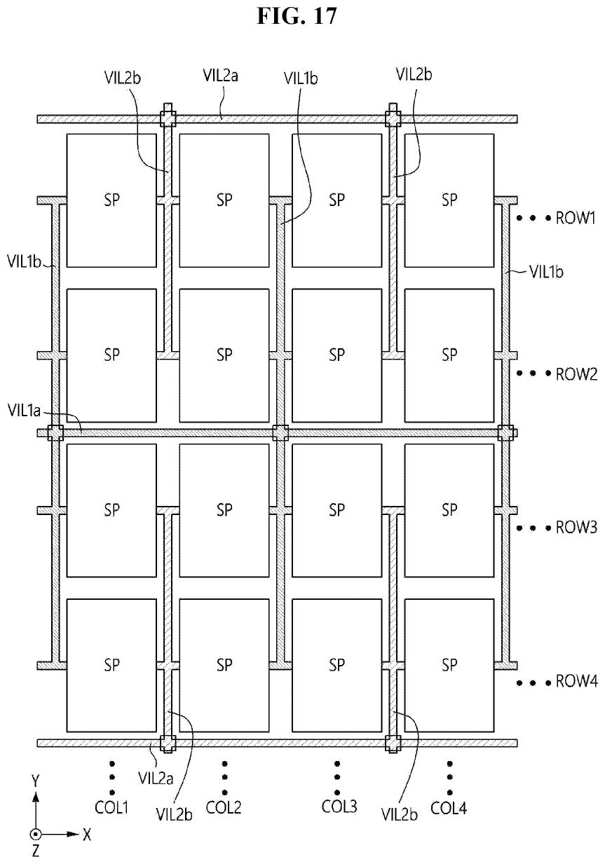

FIG. 17 is a diagram illustrating a connection relationship between a pixel and first and second initialization voltage lines in a display device of FIG. 16.

Referring to FIG. 17, pixels SP may be arranged along a plurality of rows and a plurality of columns. The horizontal portion VIL1a of the first initialization voltage line VIL1 may be disposed between the pixels SP arranged in the second row ROW2 and the pixels SP arranged in the third row ROW3. The vertical portion VIL1b of the first initialization voltage line VIL1 may be connected to the horizontal portion VIL1a of the first initialization voltage line VIL1. The vertical portion VIL1b of the first initialization voltage line VIL1 may be disposed on the left side of the pixels SP arranged in the first column COL1. The vertical portion VIL1b of the first initialization voltage line VIL1 may be disposed between the pixels SP arranged in the second column COL2 and the pixels SP arranged in the third column COL3. The vertical portion VIL1b of the first initialization voltage line VIL1 may be disposed on the right side of the pixels SP arranged in the fourth column COL4. The vertical portion VIL1b of the first initialization voltage line VIL1 may not cross the horizontal portion VIL2a of the second initialization voltage line VIL2. The vertical portion VIL1b of the first initialization voltage line VIL1 may supply the first initialization voltage received from the horizontal portion VIL1a to the pixel SP.

The horizontal portion VIL2a of the second initialization voltage line VIL2 may be disposed above the pixels SP arranged in the first row ROW1. The horizontal portion VIL2a of the second initialization voltage line VIL2 may be disposed below the pixels SP arranged in the fourth row ROW4. The vertical portion VIL2b of the second initialization voltage line VIL2 may be connected to the horizontal portion VIL2a of the second initialization voltage line VIL2. The vertical portion VIL2b of the second initialization voltage line VIL2 may be disposed between the pixels SP arranged in the first column COL1 and the pixels SP arranged in the second column COL2. The vertical portion VIL2b of the second initialization voltage line VIL2 may be disposed between the pixels SP arranged in the third column COL3 and the pixels SP arranged in the fourth column COL4. The vertical portion VIL2b of the second initialization voltage line VIL2 may not cross the horizontal portion VIL1a of the first initialization voltage line VIL1. The vertical portions VIL2b of the second initialization voltage line VIL2 may be spaced apart in the Y-axis direction with the horizontal portion VIL1a of the first initialization voltage line VIL1 interposed therebetween. The vertical portion VIL2b of the second initialization voltage line VIL2 may supply the second initialization voltage received from the horizontal portion VIL2a to the pixel SP.

The vertical portions VIL1b of the first initialization voltage line VIL1 may be spaced apart in the Y-axis direction with the horizontal portion VIL2a of the second initialization voltage line VIL2 interposed therebetween. The vertical portions VIL2b of the second initialization voltage line VIL2 may be spaced apart in the Y-axis direction with the horizontal portion VIL1a of the first initialization voltage line VIL1 interposed therebetween. Accordingly, since the vertical portions VIL1b and VIL2b of the first and second initialization voltage lines VIL1 and VIL2 are vertically spaced apart, the lengths of the vertical portions VIL1b and VIL2b may be reduced.

In addition, the horizontal portion VIL1a of the first initialization voltage line VIL1 and the horizontal portion VIL2a of the second initialization voltage line VIL2 may not be disposed between the pixels SP arranged in the first row ROW1 and the pixels SP arranged in the second row ROW2. The horizontal portion VIL1a of the first initialization voltage line VIL1 and the horizontal portion VIL2a of the second initialization voltage line VIL2 may not be disposed between the pixels SP arranged in the third row ROW3 and the pixels SP arranged in the fourth row ROW4. Accordingly, in the display device 10, it is possible to design a relatively high resolution and reduce line defect rate by reducing the number of horizontal portions VIL1a and VIL2a of the first and second initialization voltage lines VIL1 and VIL2, respectively, and reducing the length of the vertical portions VIL1b and VIL2b of the first and second initialization voltage lines VIL1 and VIL2, respectively. Horizontal portions VIL1a and VIL2a of each of the first and second initialization voltage lines VIL1 and VIL2 may increase line width to reduce line resistance.

What is claimed is:

1. A display device comprising:
first and second pixels disposed adjacent to each other, each of the first and second pixels comprising:
a light-emitting element;
a first transistor which controls a driving current which flows in the light-emitting element;
a second transistor which supplies a data voltage to a first electrode of the first transistor;
a third transistor electrically connecting a second electrode of the first transistor and a gate electrode of the first transistor; and
a fourth transistor which discharges the gate electrode of the first transistor with a first initialization voltage,
wherein the first and second pixels share a fourth-first transistor comprising a first electrode connected to the fourth transistor of the first pixel and the fourth transistor of the second pixel, and a second electrode connected to a first initialization voltage line which supplies the first initialization voltage.

2. The display device of claim 1,
wherein the first transistor and the second transistor comprise silicon-based semiconductor area, and
wherein the third transistor, the fourth transistor, and the fourth-first transistor comprise an oxide-based semiconductor area.

3. The display device of claim 1,
wherein the second transistor is turned on during a first period in response to a first gate signal of a first voltage level,
wherein the third transistor is turned on during a second period different from the first period in response to a second gate signal of a second voltage level higher than the first voltage level, and
wherein the fourth transistor and the fourth-first transistor are turned ton during a third period different from the first and second periods in response to a third gate signal of the second voltage level.

4. The display device of claim 1,
wherein each of the first and second pixels further comprise:
a fifth transistor electrically connecting a driving voltage line which supplies a driving voltage and the first electrode;
a sixth transistor electrically connecting the second electrode of the first transistor and a first electrode of the light-emitting element; and
a seventh transistor electrically connecting the first electrode of the light-emitting element and a second initialization voltage line which supplies a second initialization voltage different from the first initialization voltage.

5. The display device of claim 4,
wherein the fifth transistor, the sixth transistor, and the seventh transistor comprise a silicon-based semiconductor area.

6. The display device of claim 1,
wherein the third transistor comprises a semiconductor area, a gate electrode disposed on the semiconductor area overlapping the semiconductor area, and a bias electrode disposed below the semiconductor area and overlapping the semiconductor area, and
wherein the bias electrode of the third transistor is electrically connected to the gate electrode of the third transistor.

7. The display device of claim 1, further comprising:
a substrate;
a first active layer disposed on the substrate and including a first material;
a first gate layer disposed on the first active layer;
a second gate layer disposed on the first gate layer;
a second active layer disposed on the second gate layer and including a second material different from the first material; and
a third gate layer disposed on the second active layer.

8. The display device of claim 7,
wherein semiconductor areas of the first transistor and the second transistor are disposed in the first active layer, and
wherein semiconductor areas of the third transistor, the fourth transistor, and the fourth-first transistor are disposed in the second active layer.

9. The display device of claim 7, further comprising:
a first gate line which is disposed in the first gate layer and supplies a first gate signal to a gate electrode of the second transistor;
a second gate line which is disposed in the third gate layer and supplies a second gate signal different from the first gate signal to a gate electrode of the third transistor; and
a third gate line which is disposed in the third gate layer and supplies a third gate signal different from the first and second gate signals to each gate electrode of the fourth transistor and the fourth-first transistor.

10. The display device of claim 9,
wherein the first initialization voltage line is disposed on the third gate layer and extends in a first direction,
wherein the first initialization voltage line comprises:
a first extension portion extending in a second direction crossing the first direction; and
a second extension portion extending in a third direction crossing the second direction and connected to the fourth-first transistor.

11. The display device of claim 10,
wherein the first extension portion crosses the third gate line and does not overlap the semiconductor area of the fourth-first transistor.

12. The display device of claim 9,
wherein the first initialization voltage line is disposed on the third gate layer and extends in a first direction, and
wherein the first initialization voltage line comprises an extension portion extending in a second direction crossing the first direction so that the first initialization voltage line is connected to the fourth-first transistor through the extension portion.

13. The display device of claim 12,
wherein the extension portion crosses the third gate line and overlaps the semiconductor area of the fourth-first transistor.

14. A display device comprising:
a display panel comprising:
a display area including:
a plurality of pixels, each of the plurality of pixels comprising:
a light-emitting element;
a first transistor which controls a driving current which flows in the light-emitting element;
a second transistor which supplies a data voltage to a first electrode of the first transistor;
a third transistor electrically connecting a second electrode of the first transistor and a gate electrode of the first transistor; and
a fourth transistor which discharges the gate electrode of the first transistor with a first initialization voltage,
a first bias voltage line which supplies a first bias voltage to a bias electrode of the third transistor; and
a second bias voltage line which supplies a second bias voltage to a bias electrode of the fourth transistor; and
a non-display area surrounding the display area.

15. The display device of claim 14,
further comprising a circuit board which supplies voltages and signals to the display panel,
wherein the display panel further comprises a display pad unit connected to the circuit board, and
wherein the non-display area comprises a bias lead line electrically connecting the first bias voltage line or the second bias voltage line to the display pad unit.

16. The display device of claim 14,
wherein the first bias voltage line is electrically insulated from a gate electrode of the third transistor, and the second bias voltage line is electrically insulated from a gate electrode of the fourth transistor.

17. A display device comprising:
a plurality of pixels arranged along a plurality of rows and a plurality of columns; each of the plurality of pixels comprising:
a light-emitting element;
a first transistor which controls a driving current flowing in the light-emitting element;
a second transistor which supplies a data voltage to a first electrode of the first transistor;
a third transistor electrically connecting a second electrode of the first transistor and a gate electrode of the first transistor;
a fourth transistor;
a fifth transistor;
a sixth transistor electrically connecting the second electrode of the first transistor and a first electrode of the light-emitting element; and
a seventh transistor:
a first initialization voltage line which supplies a first initialization voltage to the plurality of pixels;
a second initialization voltage line which supplies a second initialization voltage different from the first initialization voltage to the plurality of pixels; and
a driving voltage line which supplies a driving voltage to the plurality of pixels,
wherein the fourth transistor discharges the gate electrode of the first transistor with the first initialization voltage;
the fifth transistor electrically connects the driving voltage line and the first electrode of the first transistor; and
the seventh transistor electrically connects the first electrode of the light emitting element and the second initialization voltage line,
wherein the first and second initialization voltage lines are disposed between adjacent rows of some of the plurality of rows and are not disposed between the adjacent rows of some others of the plurality of rows.

18. The display device of claim 17,
wherein the first initialization voltage line comprises a horizontal portion extending in a first direction and a vertical portion connected to the horizontal portion and extending in a second direction crossing the first direction,
wherein the second initialization voltage line comprises a horizontal portion extending in the first direction and a vertical portion connected to the horizontal portion and extending in the second direction.

19. The display device of claim 18,
wherein the horizontal portion of the second initialization voltage line is provided in plural, and
wherein the horizontal portion of the first initialization voltage line is disposed between the horizontal portions of the second initialization voltage line and crosses the vertical portion of the second initialization voltage line.

20. The display device of claim 18,
wherein the vertical portion of the first initialization voltage line is provided in plural,
wherein the vertical portions of the first initialization voltage line adjacent in the second direction are spaced apart from each other with the horizontal portion of the second initialization voltage line interposed therebetween, and
wherein the vertical portions of the second initialization voltage line adjacent in the second direction are spaced apart from each other with the horizontal portion of the first initialization voltage line interposed therebetween.
